(19) United States
(12) Patent Application Publication
(10) Pub. No.: US 2025/0258233 A1
(43) Pub. Date: Aug. 14, 2025

(54) Software-controlled Battery Charging and Monitoring of Access CPE Devices

(71) Applicant: Charter Communications Operating, LLC, St. Louis, MO (US)

(72) Inventor: Shlomo OVADIA, Denver, CO (US)

(21) Appl. No.: 18/439,031

(22) Filed: Feb. 12, 2024

(51) Int. Cl. G01R 31/367; G01R 31/3842; G06Q 50/06

(52) U.S. Cl. CPC G01R 31/367; G01R 31/3842; G06Q 50/06

(57) ABSTRACT

Systems, methods, and devices for performing charging of at least one battery of a customer premises device (CPE). These may include calculating available electricity energy from a power supply unit (PSU), and charging the at least one battery of the CPE using the available electricity energy from the PSU. Some may include measuring electric energy usage of the CPE. Some may include determining whether the electric energy usage at the CPE exceeds an idle threshold and/or is less than a charge threshold, calculating the available electricity energy from the PSU using a representation of electric energy usage of the CPE over a duration in response to the electric energy usage at the CPE exceeding the idle threshold and/or being less than the charge threshold, and using an idle electric energy usage of the CPE in response to the electric energy usage at the CPE not exceeding the idle threshold.

### BACKGROUND

Multiple system operators, which may include cable network operators, use as many as millions of field-deployed access customer premises devices (CPE) in their networks, serving residential and corporate subscribers. Many types of CPEs may be physically located at subscribers' local networks. A power supply unit (PSU) of a CPE is designed to provide a maximum output current under adverse operating conditions. However, PSU design may be limited to provide the maximum output current to support critical functions of the CPE only, but fail to provide sufficient output current to support other functions of the CPE such as charging a battery.

### SUMMARY

The various aspects include methods of performing charging of at least one battery of a customer premises device (CPE. The various aspects may include calculating available electric energy from a power supply unit (PSU) of the CPE, and charging the at least one battery of the CPE using the available electric energy from the PSU, such that the maximum energy available to charge the at least one battery is the maximum available energy from the PSU.

Some aspects may further include measuring electric energy usage of the CPE, and determining whether the measured electric energy usage of the CPE exceeds an idle threshold, in which calculating the available electric energy from the PSU may include calculating the available electric energy from the PSU using a representation of electric energy usage of the CPE over a duration in response to determining that the electric energy usage at the CPE exceeds the idle threshold, and in which calculating the available electric energy from the PSU may include calculating the available electric energy from the PSU using an idle electric energy usage of the CPE in response to determining that the electric energy usage at the CPE does not exceed the idle threshold.

In some aspects, calculating the available electric energy from the PSU may include calculating a first available electric energy from the PSU. Some aspects may further include calculating a representation of electric energy usage of the CPE over a duration, and calculating a second available electric energy from the PSU of the CPE using the representation of electric energy usage of the CPE over the duration, in which charging the at least one battery of the CPE using the available electric energy from the PSU may include charging the at least one battery of the CPE using the second available electric energy from the PSU.

Some aspects may further include measuring electric energy usage of the CPE, in which calculating the first available electric energy from the PSU may include calculating the first available electric energy from the PSU using the measuring electric energy usage of the CPE, and determining whether the first available electric energy from the PSU exceeds a charge threshold, in which calculating the second available electric energy from the PSU using the representation of electric energy usage of the CPE over the duration may include calculating the second available electric energy from the PSU using the representation of electric energy usage of the CPE over the duration in response to determining that the first available electric energy from the PSU exceeds the charge threshold.

In some aspects, calculating the available electric energy from the PSU may include calculating a first available electric energy from the PSU using an idle electric energy usage of the CPE.

Some aspects may further include measuring electric energy usage of the CPE, calculating a second available electric energy from the PSU of the CPE using the measured electric energy usage of the CPE, and determining whether the second available electric energy from the PSU exceeds a charge threshold, in which calculating the first available electric energy from the PSU using the idle electric energy usage of the CPE may include calculating the first available electric energy from the PSU using the idle electric energy usage of the CPE in response to determining that the second available electric energy from the PSU exceeds the charge threshold.

In some aspects, calculating the available electric energy from the PSU may include calculating the available electric energy from the PSU using a value representative of electric energy usage at the CPE operating with maximum upstream and downstream data throughputs with a foreign exchange subscriber port ringing even. Some aspects may further include determining whether the available electric energy from the PSU exceeds a charge threshold.

Some aspects may further include streaming battery status information from the CPE to a remote monitoring device.

Some aspects may further include receiving, at the CPE, a battery charge command from a remote monitoring device, in which charging the at least one battery of the CPE using the available electric energy from the PSU may include charging the at least one battery of the CPE in response to receiving the battery charge command.

Further aspects may include a computing device having a processing system configured to perform one or more operations of the methods summarized above. Further aspects may include a non-transitory processing system-readable storage medium having stored thereon processing system-executable instructions configured to cause a processing system of a computing device to perform operations of the methods summarized above. Further aspects include a computing device having means for performing functions of the methods summarized above.

### BRIEF DESCRIPTION OF THE DRAWINGS

The accompanying drawings, which are incorporated herein and constitute part of this specification, illustrate exemplary embodiments, and together with the general description given above and the detailed description given below, serve to explain the features of various embodiments.

FIG. 1 is a block diagram of an example communication network that includes a customer premises device (CPE) and a remote monitoring server suitable for use with various embodiments.

FIGS. 2A and 2B are block diagrams of example CPEs suitable for use with various embodiments.

FIGS. 3A and 3B are block diagrams of an example battery charging system of a CPE suitable for use with various embodiments.

FIGS. 4A-4D are process flow diagrams that illustrate a method for charging a battery of a CPE in accordance with the various embodiments.

FIGS. 5A and 5B are block diagrams of example CPEs connected to a remote monitoring device suitable for use with various embodiments.

FIG. 6 block diagrams of an example a system on chip of a CPE suitable for use with various embodiments.

FIG. 7 is a process flow diagram that illustrates a method for remote battery charging monitoring and control for a battery of a CPE in accordance with the various embodiments.

FIG. 8 is a component diagram of an example server suitable for implementing the various embodiments.

FIG. 9 is a component diagram of an example network device suitable for use with various embodiments.

### DETAILED DESCRIPTION

The various embodiments will be described in detail with reference to the accompanying drawings. Wherever possible, the same reference numbers will be used throughout the drawings to refer to the same or like parts. References made to particular examples and implementations are for illustrative purposes, and are not intended to limit the scope of the invention or the claims.

The term “service provider network” is used generically herein to refer to any network suitable for providing consumers with access to the Internet or IP services over broadband connections, and may encompass both wired and wireless networks/technologies. Examples of wired network technologies and networks that may be included within a service provider network include cable networks, fiber optic networks, hybrid-fiber-cable networks, Ethernet, local area networks (LAN), metropolitan area networks (MAN), wide area networks (WAN), networks that implement the data over cable service interface specification (DOCSIS), networks that utilize asymmetric digital subscriber line (ADSL) technologies, etc. Examples of wireless network technologies and networks that may be included within a service provider network include third generation partnership project (3GPP), long term evolution (LTE) systems, third generation wireless mobile communication technology (3G), fourth generation wireless mobile communication technology (4G), fifth generation wireless mobile communication technology (5G), global system for mobile communications (GSM), universal mobile telecommunications system (UMTS), high-speed downlink packet access (HSDPA), 3GSM, general packet radio service (GPRS), code division multiple access (CDMA) systems (e.g., cdmaOne, CDMA2000TM), enhanced data rates for GSM evolution (EDGE), advanced mobile phone system (AMPS), digital AMPS (IS-136/TDMA), evolution-data optimized (EV-DO), digital enhanced cordless telecommunications (DECT), Worldwide Interoperability for Microwave Access (WiMAX), wireless local area network (WLAN), Wi-Fi Protected Access I & II (WPA, WPA2), Bluetooth®, land mobile radio (LMR), and integrated digital enhanced network (iden). Each of these wired and wireless technologies involves, for example, the transmission and reception of data, signaling and/or content messages.

Any references to terminology and/or technical details related to an individual wired or wireless communications standard or technology are for illustrative purposes only, and not intended to limit the scope of the claims to a particular communication system or technology unless specifically recited in the claim language.

The term “user equipment (UE)” may be used herein to refer to any one or all of satellite or cable set top boxes, laptop computers, rack mounted computers, routers, cellular telephones, smart phones, personal or mobile multi-media players, personal data assistants (PDAs), customer premises equipment (CPE), personal computers, tablet computers, smart books, palm-top computers, desk-top computers, wireless electronic mail receivers, multimedia Internet enabled cellular telephones, wireless gaming controllers, streaming media players (such as, ROKU™), smart televisions, digital video recorders (DVRs), modems, routers, network switches, residential gateways (RG), access nodes (AN), bridged residential gateway (BRG), fixed mobile convergence products, home networking adapters and Internet access gateways that enable consumers to access communications service providers' services and distribute them around their house via a local area network (LAN), and similar electronic devices which include a programmable processor and memory and circuitry for providing the functionality described herein.

The terms “component,” “system,” and the like may be used herein to refer to a computer-related entity (e.g., hardware, firmware, a combination of hardware and software, software, software in execution, etc.) that is configured to perform particular operations or functions. For example, a component may be, but is not limited to, a process running on a processor, a processor, an object, an executable, a thread of execution, a program, and/or a computing device. By way of illustration, both an application running on a computing device and the computing device may be referred to as a component. One or more components may reside within a process and/or thread of execution and a component may be localized on one processor or core and/or distributed between two or more processors or cores. In addition, these components may execute from various non-transitory computer readable media having various instructions and/or data structures stored thereon. Components may communicate by way of local and/or remote processes, function or procedure calls, electronic signals, data packets, memory read/writes, and other known computer, processor, and/or process related communication methodologies.

The terms “customer premises device” or “customer premises equipment”, which both may be abbreviated as “CPE”, may include a cable modem, digital subscriber line modem, router, switch, firewall, packet filter, wireless access point, residential gateway, etc. that may provide network connectivity to residential and/or commercial (e.g., business, non-profit, worksite, retail, hospitality, service provider, etc. location) network. A CPE may allow user equipment (UE) devices on a local area network (LAN) to connect to a wide area network (WAN) and ultimately the Internet.

The term “electric energy” may refer to, individually and/or in any combination, electric current, voltage, or power. Similarly, any functions implemented by devices, components, circuits, hardware, processor systems, etc., such as use, measurement, calculation, identification, determination, charging, etc. regarding electric energy may be implemented based on, individually and/or in any combination, electric current, voltage, or power.

Multiple system operators, which may include cable network operators, use as many as millions of field-deployed access customer premises devices (CPE; or customer premises equipment) in their networks, serving residential and corporate subscribers. Many types of CPEs may be physically located at subscribers' local area networks. A power supply unit (PSU) of a CPE is designed to provide a maximum output current under adverse operating conditions. Current PSU designs are limited to providing the maximum output current to support critical functions of the CPE under the adverse operating conditions. Critical functions may include some, all, or only necessary functions of the CPE. The PSU designs may be limited by cost, form factor of a main PSU body, etc. However, such PSU designs have difficulty to provide sufficient output current to support other functions of the CPE, as the PSU is fully engaged to support the critical functions of the CPE. For example, current PSUs may have difficulty to charge CPE batteries as the PSU output supply may be devoted to supporting the CPE critical functions. The additional demands of also charging a CPE battery may be beyond the capabilities of the PSU, while CPE critical functions are on-going.

Some CPEs may include at least one battery that needs to be charged after a charge level of the battery is reduced due to use or periods of disuse of the at least one battery. The at least one battery may be a battery of a bank of batteries or a battery module. The at least one battery may include two or more batteries in which the at least one battery may be part of a pair of batteries. For example, the at least one battery may be relied upon in instances when power to the CPE from the PSU is lost, such as during power outage from an electrical grid. The at least one battery may output power to maintain operation of the CPE during the power loss from the PSU. However, output from the at least one battery reduces the electric energy availability at the at least one battery. At some point, the at least one battery will benefit from a recharge process to replenish the discharged electric energy. In particular, upon the restoration of power is restored following a power outage from the electrical grid, the CPE battery may seek a recharge to replenish its power storage capabilities. However, a typical PSU may not be able to provide sufficient electric energy to both support the critical functions of the CPE and recharge the battery concurrently. Since the support of the critical functions of the CPE is a priority, secondary functions such as recharging the CPE battery may not be supported at all times.

Various embodiments disclosed herein seek to overcome the foregoing problems. The embodiments may provide a charger of the CPE that may be configured to identify instances during CPE operation at which there is sufficient electric energy available from the PSU to provide a charge operation of the at least one battery. The charger may be configured to charge the at least one battery using the electric energy from the PSU based on availability of sufficient electric energy from the PSU to charge the at least one battery. The charger may identify availability of sufficient electric energy available from the PSU to charge the at least one battery based on electric energy usage by the CPE and PSU electric energy output capabilities. The charger may charge the at least one battery in response to identifying availability of the sufficient electric energy from the PSU to charge the at least one battery. For example, there may be sufficient electrical energy from the PSU in instances in which critical functions of the CPE require reduced amounts of electrical energy such as the CPE operating in idle mode.

In some embodiments, the CPE may be actively operating, such as in an active mode (i.e., not in an idle or standby mode). The CPE actively operating may include implementing varying levels (e.g., maximum, high, medium, low, etc.) of upstream and downstream throughputs. The CPE actively operating may also include or not include asynchronous foreign exchange subscriber (FXS) port ringing while implementing the varying levels of upstream and downstream throughputs. In some embodiments, the CPE may be inactively operating, such as not in an active mode or in an idle or standby mode. For example, the CPE inactively operating may include a power saving mode, which may be implemented during a power loss from the electrical grid. The charger may measure electric energy usage at the CPE. The electric energy usage at the CPE may be used by the charger to identify how the CPE is operating. The measurement of electric energy usage at the CPE may be used by the charger to identify whether the CPE is using too much of the electric energy from the PSU such that the PSU may not also support the charging of the at least one battery at present time. For example, the electric energy usage at the CPE by critical functions may be too great for there to be sufficient electric energy from the PSU to charge the at least one battery under the current electric energy consumption conditions.

A calculation, by the charger, of the electric energy available from the PSU to charge the at least one battery may vary based on how the CPE is operating. For example, electric energy usage at the CPE over a duration may be used to calculate the electric energy available from the PSU for the CPE operating in an active mode. For another example, electric energy usage at the CPE at a discreet moment may be used to calculate the electric energy available from the PSU for the CPE operating in an idle mode. The electric energy usage at the CPE may be compared with an electric energy output capability of the PSU by the charger to calculate the electric energy available from the PSU to charge the at least one battery.

One or more criterion for identifying whether there is sufficient electric energy available from the PSU to charge the at least one battery may vary depending on how the CPE is operating. For the CPE in an active mode, the criterion for identifying whether there is sufficient electric energy available from the PSU may be a comparison of the electric energy available from the PSU and an electric energy output capability of the PSU.

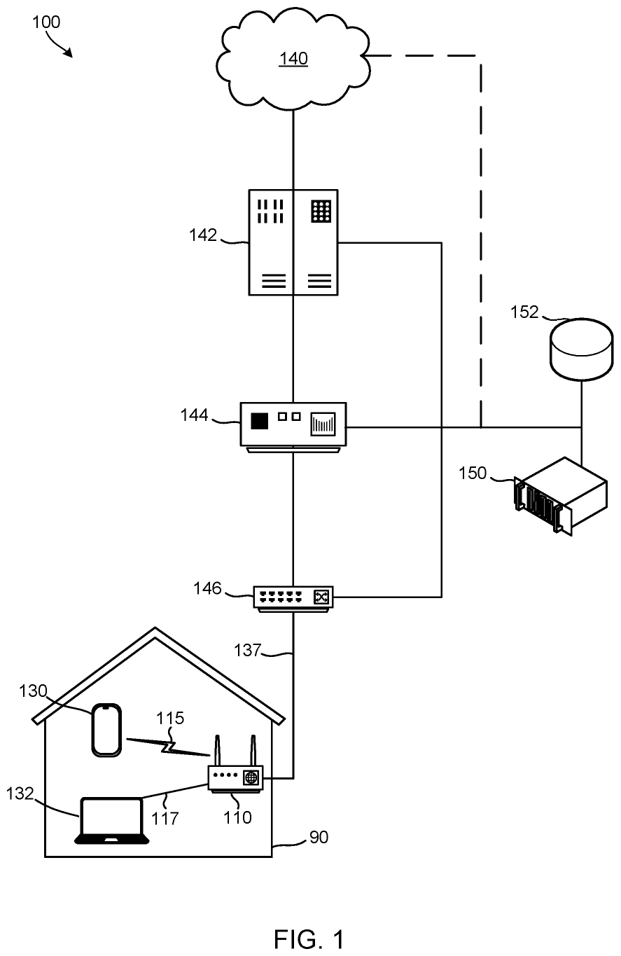

FIG. 1 illustrates an example of a communication network 100, such as an internet network, in accordance with various embodiments. With reference to FIG. 1, the communication network 100 may include various network operations sites such as one or more headends 142, hubs 144, or nodes 146, any of which may be or be part of a cable-plant. The cable plant may include hybrid fiber coax (HFC) architecture or Distributed Access Architecture (DAA). Each of the network operations sites 142, 144, 146 may be configured to provide connectivity service between one or more customer premises equipment (CPE; or customer premises equipment) 110 and a communication network 140 (e.g., the Internet). Each of the network operations sites 142, 144, 146 may include network hardware to enable and control the connectivity service, such as a channel modulator, a frequency multiplexer, an amplifier, a tap, a splitter, a mode, a cable management termination system, a switch, a router, a quadrature amplitude modulator, etc. The CPE 110, the network operations sites 142, 144, 146, and the communication network 140 may be coupled by one or more communication links 137.

One or more CPEs 110 may be located at one or more residential or commercial locations 90 and connect a user equipment (UE) devices 130, 132 to the communication network 140. The CPE 110 may be a network device that enables communication between networked devices, like the one or more UE devices 130, 132 and the communication network 140. The CPE 110 may include the functionality of a modem or router, which enables the UE devices 130, 132 access to the communication network 140. In some embodiments, the CPE 110 may be multiple devices that may include the functionality of a modem or router. In some embodiments, the CPE 110 may be a modem operating in a routing mode and connected wireless access point. In some embodiments, the CPE 110 may be a gateway device. A non-exhaustive and non-limiting list of examples of the CPE 110 may include a D4.0/D3.1 residential embedded multimedia terminal adapter (eMTA), D4.0/D3.1 small-medium business (SMB) eMTA, advanced wireless gateway (AWG), 1/10G Ethernet passive optical network (EPON) optical network unit (ONU), etc.

The UE device 130, 132 may be any electronic device equipped with at least a processor, communication systems, and memory configured to receive and send data of the user computing device 130, 132 via the communication network 140. The UE device 130, 132 may be coupled to the CPE 110 by a short-range wireless connection 115 (e.g., Wi-Fi, Bluetooth, etc.) or wired connection 117 (e.g., Ethernet, etc.). The CPE 110 may be coupled to the network operations sites 142, 144, 146 and the communication network 140 by one or more communication links 137. The UE device 130, 132 alternatively, or additionally, may be coupled to the network operations sites 142, 144, 146 and the communication network 140 by a long-range wireless connection (not shown).

Each of the network operations sites 142, 144, 146 may be connected to remotely, such as via the communication network 140, or include locally a computing device 150 and a data storage device 152. The computing device 150 may be any electronic device equipped with a processing system, communication systems, and memory, such as a server. The processing system may include one or more processors, processor cores, controllers, microcontrollers, etc. The processing system of the computing device 150 may be configured to execute computer software. The computing device 150 may be configured to process data from and transmit data or commands to the CPE 110 via the one or more communication links 137, the network operations sites 142, 144, 146, or the communication network 140. The data storage device 152 may be any non-volatile, processor-system readable media, such as a solid-state storage device, optical storage device, magnetic storage device, etc. The data storage device 152 may be configured to persistently store data from and provide access to the data to the computing device 150.

In some embodiments, the computing device 150 and the data storage device 152 may be located at the communication network 140, such as part of a cloud computing network. The cloud computing network may include multiple computing devices 150 and data storage devices 152 configured to, individually or together, implement cloud-based services accessible by the UE device 130, 132, the CPE 110, or the network operations sites 142, 144, 146.

In some embodiments, any combination of the computing device 150 and the data storage device 152 may be located locally at the network operations sites 142, 144, 146 or remotely to the network hardware sites 142, 144, 146. For example, both computing devices 150 and data storage devices 152 may be located locally at any of the network operations sites 142, 144, 146. For another example, both the computing device 150 and the data storage device 152 may be located remotely from each of the network operations sites 142, 144, 146. For another example, computing devices 150 may be located locally at any of the network operations sites 142, 144, 146 and the data storage device 152 may be located remotely from each of the network operations sites 142, 144, 146.

The communication links 137 may use a variety of wireless (e.g., 5g-NR(u), LTE, Citizens Broadband Radio Service (CBRS), etc.) or wired networks (e.g., Ethernet, TV cable, telephony, fiber optic and other forms of physical network connections) that may use one or more communication protocols, such as Ethernet, Point-To-Point protocol, High-Level Data Link Control (HDLC), Advanced Data Communication Control Protocol (ADCCP), and Transmission Control Protocol/Internet Protocol (TCP/IP).

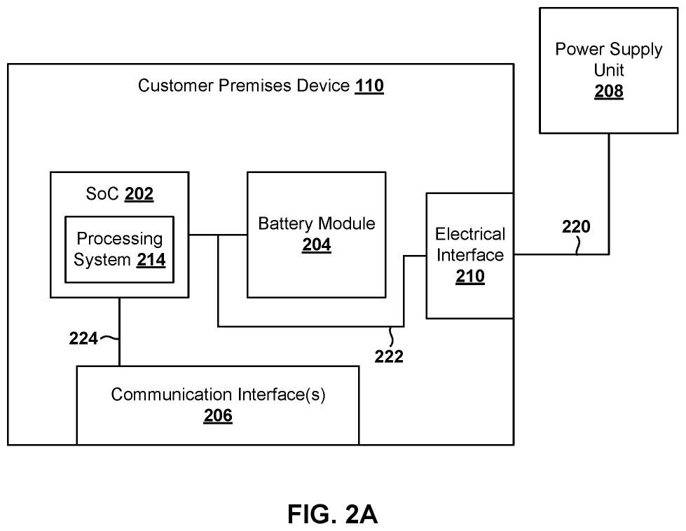

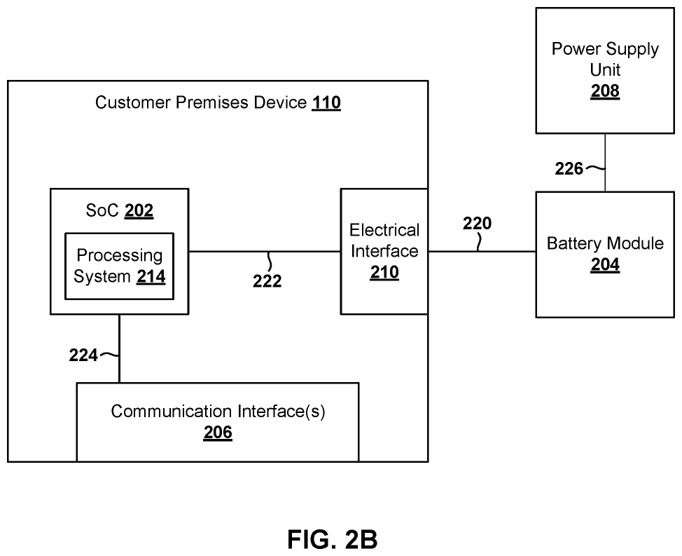

FIGS. 2A and 2B illustrate examples of the CPE 110 suitable for use with various embodiments. With reference to FIGS. 1-2B, the CPE 110 may include a system on chip (SoC) 202, one or more communication interfaces 206, a battery module 204, and a PSU 208. The SoC 202 may include a processing system 214, communication systems, and memory. The processing system 214 may include one or more processors, processor cores, controllers, microcontrollers, etc. The SoC 202 may be configured to control various functions of the CPE 110. The functions of the CPE may include communications or access functions for communication between one or more connected UE devices (e.g., UE device 130, 132 in FIG. 1) and communication networks (e.g., communication network 140 in FIG. 1). The one or more communication interfaces 206 may include processing systems, hardware, and physical ports configured for implementing communication functions of the CPE 110. A non-exhaustive and non-limiting list of examples of physical ports of the one or more communication interfaces 206 may include voice ports (e.g., RJ11 ports), 10Gb Ethernet ports (e.g., RJ45 ports), 1Gb Ethernet ports (e.g., RJ45 ports), coaxial radio frequency ports (e.g., F81 connector), etc. The SoC 202 and the one or more communication interfaces 206 may be connected via one or more communication buses 224.

The PSU 208 may be configured to provide electric energy from a power source (not shown) to the CPE 110. For example, the PSU 208 may connect to an electrical outlet and provide electric energy from the electrical outlet to the CPE 110. The PSU 208 may condition the electric energy from the power source to provide a stable and regulated electrical supply to the CPE 110. The PSU 208 may adjust the output of electric energy to the CPE 110 to meet the precise electric energy requirements of the CPE 110. The PSU 208 may be designed to optimize the electric energy quality, minimize electrical noise and interference, and enhance the reliability and efficiency of the CPE 110. The PSU 208 may provide electric energy to the CPE 110 via an electrical connector 220 connected to an electrical interface 210 of the CPE 110. In some embodiments, the electrical connector 220 may include an electrical conduit, wire, lead, bus, pin, printed circuit board, etc. In some embodiments, the electrical interface 210 may include an inline connection or a chassis connection having a physical port, such as an EIAJ jack, a USB port, etc. to which the electrical connector 220 may be connected. The electrical interface 210 may connect the electrical connector 220 and an electrical connector 222. In some embodiments, the electrical connector 220 may include an electrical conduit, wire, lead, bus, pin, printed circuit board, etc. The electric energy may be distributed within the CPE 110, such as at least to the SoC 202, via the electrical connector 222.

An optimized design of the PSU 208 may include the PSU 208 configured to provide a maximum electric energy sufficient to support the critical functions of the CPE 110. In instances in which the critical functions of the CPE 110 demand large amounts of electrical energy, the maximum electric energy provided by the PSU 208 may be insufficient to support the critical functions of the CPE 110 concurrently with other functions of the CPE 110 (e.g., battery charge functions). Consumption of at least part of the maximum electric energy by the critical functions of the CPE 110 may result in insufficient electric energy from the PSU 208 to support the other functions of the CPE 110. Critical functions of the CPE 110 may include, for example, the communications or access functions for communication between one or more connected UE devices (e.g., UE device 130, 132 in FIG. 1) and communication networks. Other functions of the CPE 110 may include charging the one or more batteries of the battery module 204.

For a non-limiting example, the PSU 208 may be designed to provide electric energy sufficient to support the critical functions of the CPE 110 that may use an average maximum current of greater than 2A. For example, a D4.0 residential eMTA may use an average maximum current of approximately 2.22A for implementing high-throughput traffic and asynchronous foreign exchange subscriber (FXS) port ringing. For another example, a D4.0 SMB eMTA may use an average maximum current of approximately 2.67A for implementing high-throughput traffic and asynchronous FXS port ringing. The PSU 208 may be incapable of providing electric power to support the critical functions of the CPE 110 as well as providing additional electric energy sufficient to charge the one or more batteries of the battery module 204. For example, the PSU 208 may be unable to provide an additional electric energy to the average maximum current. For example, the average maximum current may be consumed by the CPE 110 implementing the critical functions and the PSU 208 may not be able to provide an additional 500 mA needed to charge the one or more batteries of the battery module 204.

In the example of FIG. 2A, the CPE 110 may include the battery module 204 within a housing of the CPE 110. The PSU 208 may provide electric energy to the battery module 204 via the electrical connector 220, the electrical interface 210, and the electrical connector 222. In the example of FIG. 2B, the CPE 110 may include the battery module 204 external to the housing of the CPE 110. The PSU 208 may provide electric energy to the battery module 204 via an electrical connector 226 and to the CPE 110 via the electrical connector 220, the electrical interface 210, and the electrical connector 222. The electrical connector 220 may be connected to or an extension of the electrical connector 226. In some embodiments, the electrical connector 226 may include an electrical conduit, wire, lead, bus, pin, printed circuit board, etc.

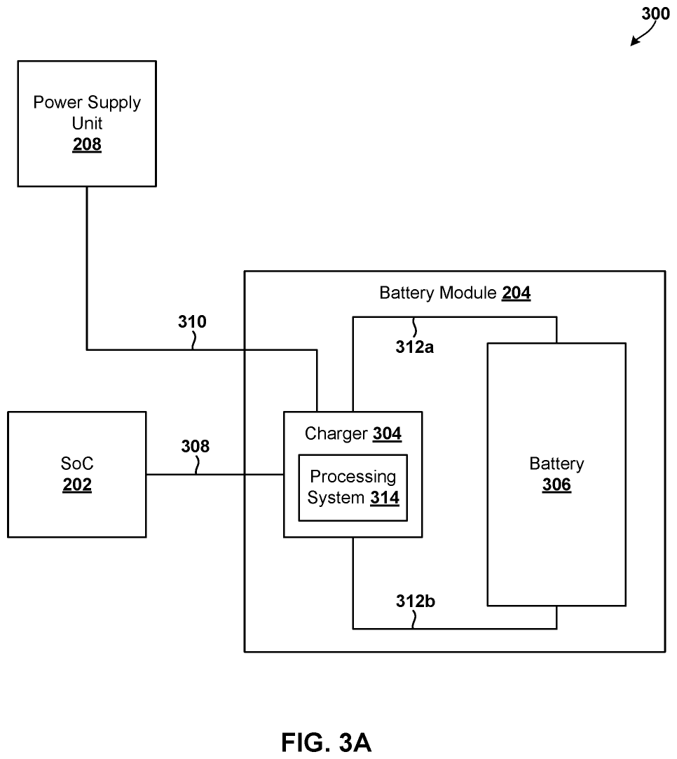

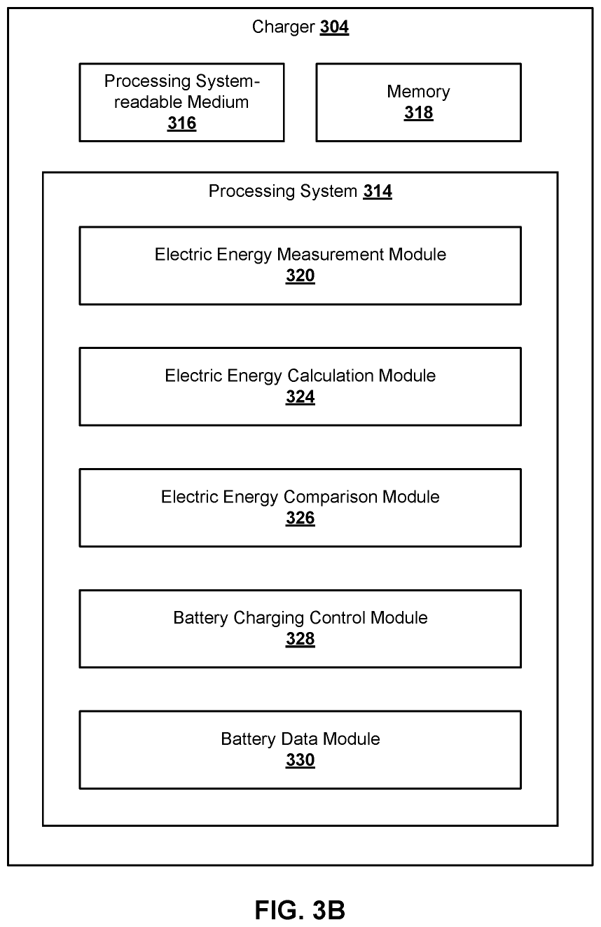

FIGS. 3A and 3B illustrate an example of a battery charging system 300 of the CPE 110 suitable for use with various embodiments. With reference to FIGS. 1-3B the battery charging system 300 may include the SoC 202 and the battery module 204. The battery module 204 may include a charger 304 and a battery 306, which may include one or more batteries. For example, the battery 306 may be a bank of batteries. For another example, the battery 306 may be two or more batteries in which batteries may be arranged in pairs. The charger 304 may be electrically connected to the PSU 208 and receive electric energy from the PSU 208 via an electrical connector 310 (e.g., electrical interface 210, electrical connector 220, 222, 226 in FIGS. 2A and 2B). In some embodiments, the electrical connector 310 may include an electrical conduit, wire, lead, bus, pin, printed circuit board, etc. The charger 304 and the battery 306 may be electrically connected at a positive polarity terminal and a negative polarity terminal of the battery 306 by respective electrical connectors 312a, 312b. In some embodiments, the connector 312a, 312b may include an electrical conduit, wire, lead, bus, pin, printed circuit board, etc. The charger 304 may include electrical circuitry configured for providing electric energy to the battery 306 for charging. The SoC 202 and the charger 304 may be electrically connected via an electrical connector 308 (e.g., electrical connector 222, 226 in FIGS. 2A and 2B) enabling the battery module 204 to provide electric energy from the battery 306 to the SoC 202.

Referring to FIG. 3B, the charger 304 may include hardware or a processing system 314 configured with software or firmware processor-executable instructions, for implementing functions of the charger 304. The processing system 314 may include one or more processors, processor cores, controllers, microcontrollers, etc. Such functions of the charger 304 may include any combination of controlling charging of the battery 306, measuring a level of charge of the battery 306, measuring an electric energy usage of the CPE 110, calculating a representation of electric energy usage of the CPE 110 over a duration, calculating an available electric energy from the PSU 208, comparing various measured or calculated electric energy to levels or thresholds of electric energy, etc. In some embodiments, the software or firmware processor-executable instructions may be configured as modules, including: an electric energy measurement module 320; an electric energy calculations module 324; an electric energy comparison module 326; a battery charging control module 328; and a battery data module 330.

The software or firmware, including the modules 320-330, for implementing the functions of the charger 304 may be stored at a processing system-readable medium 316 (e.g., non-volatile memory, volatile memory, main memory, cache memory, etc.). The software or firmware, including the modules 320-330, for implementing the functions of the charger 304 may be accessed by the processing system 314 from the processing system-readable medium 316. The charger 304 may be configured with a memory 318 (e.g., an electrically programable read only memory (EPROM), electronic fuse (eFuse), register, etc.) that is accessible by the processing system 314. The memory 318 may be configured to store an electric energy rating of the PSU 208. The energy rating of the PSU 208 may indicate to the processing system 314 a maximum amount of electric energy provided by the PSU 208.

In some embodiments, the charger 304 may include hardware (e.g., resistors, transistors, capacitors, inductors, etc.) configured as an electric energy measuring circuit. The hardware of the charger 304 may receive or sense electric energy at one or more of the electrical connectors 310, 312a, 312b and output an electric energy measurement signal to the processing system 314. The electric energy measurement signal may be configured to indicate to the processing system 314 an amount of electric energy being used by the CPE 110.

Implementing the electric energy measurement module 320, the processing system 314 may interpret the electric energy measurement signal. Electric energy usage information interpreted from the electric energy measurement signal may be used by the processing system 314 to implement functions of the charger 304. For example, the processing system 314 may measure electric energy usage by the CPE 110 at a discreet moment or over a duration. Implementing the electric energy calculations module 324, the processing system 314 may calculate a representation (e.g., an average, a mean, etc.) of the electric energy usage by the CPE 110 over the duration. Implementing the electric energy comparison module 326, the processing system 314 may compare the measured or representation of electric energy usage by the CPE 110 to one or more of the electric energy rating of the PSU 208 or thresholds of electric energy. In various embodiments, the thresholds of electric energy may include values representative, individually and/or in any combination, of electric current, voltage, or power.

The thresholds of electric energy may include an idle threshold. The idle threshold may be a value representative of a certain amount of electric energy used by the CPE 110 operating in an idle mode. The thresholds of electric energy may include a charge threshold. The charge threshold may be a value representative of a minimum amount of electric energy from the PSU 208 sufficient to charge the battery 306. For example, the charge threshold may be less than 1A, such as approximately 500 mA, approximately 1A, or more than 1A. The thresholds of electric energy may include a level threshold. The level threshold may be a value representative of a charge level for a fully charged battery 306.

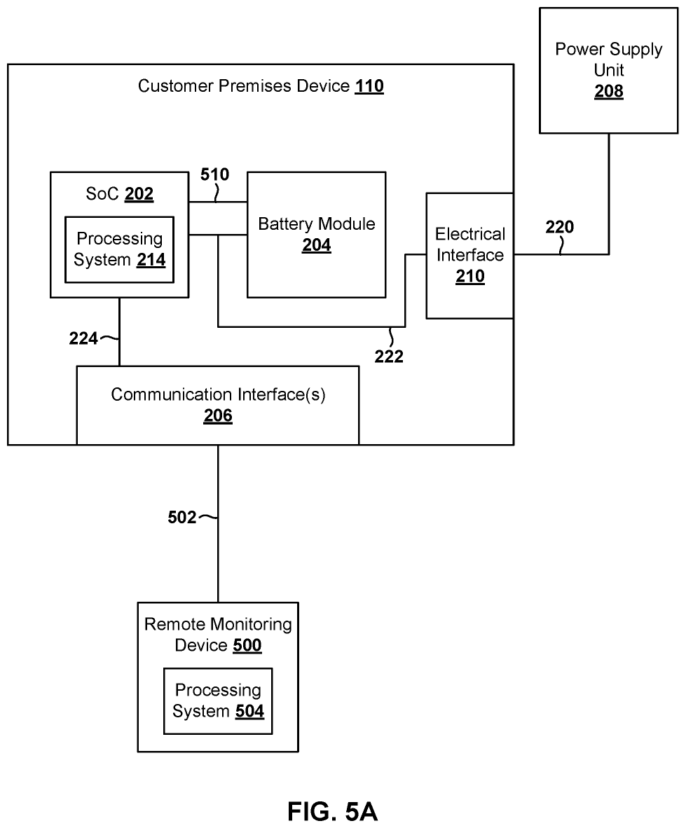

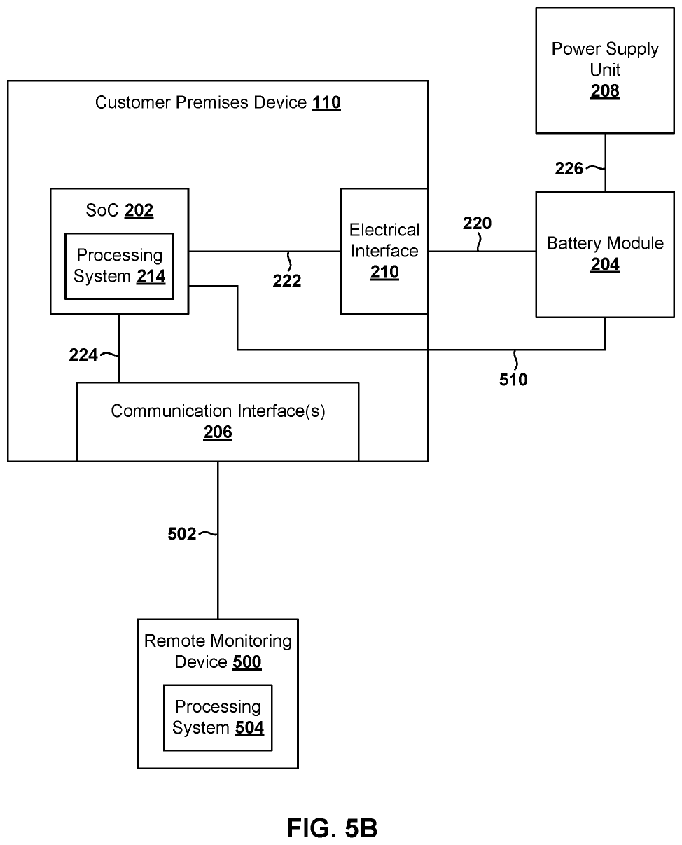

The electric energy measurement signal based on the electric energy at one or more of the electrical connectors 312a, 312b may be configured to indicate to the processing system 314 a level of charge of the battery 306. Implementing the electric energy measurement module 320, the processing system 314 may interpret the electric energy measurement signal. Information interpreted from the electric energy measurement signal may be used by the processing system 314 to implement functions of the charger 304. For example, implementing the electric battery charging control module 328, the processing system 314 may control whether and how to charge the battery 306. The processing system 314 may base whether and how to charge the battery 306 on results of implementing other modules 320-326. Implementing the battery data module 330, the processing system 314 may provide the level of charge of the battery 306 to the SoC 202 for use in accessing cloud-based services. Accessing the cloud-based services may be achieved by transmitting the level of charge of the battery 306 (or telemetry) data for the battery 306 from the CPE to a remote monitoring device (not shown; computing device 150, remote monitoring device 500 in FIGS. 5A, 5B), as described further herein.

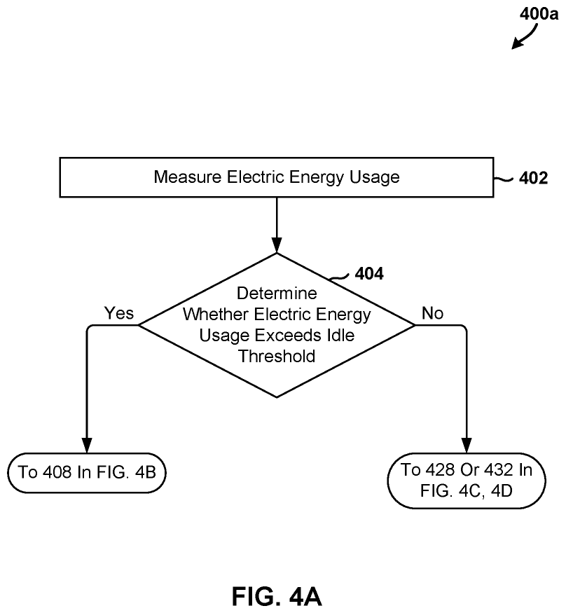

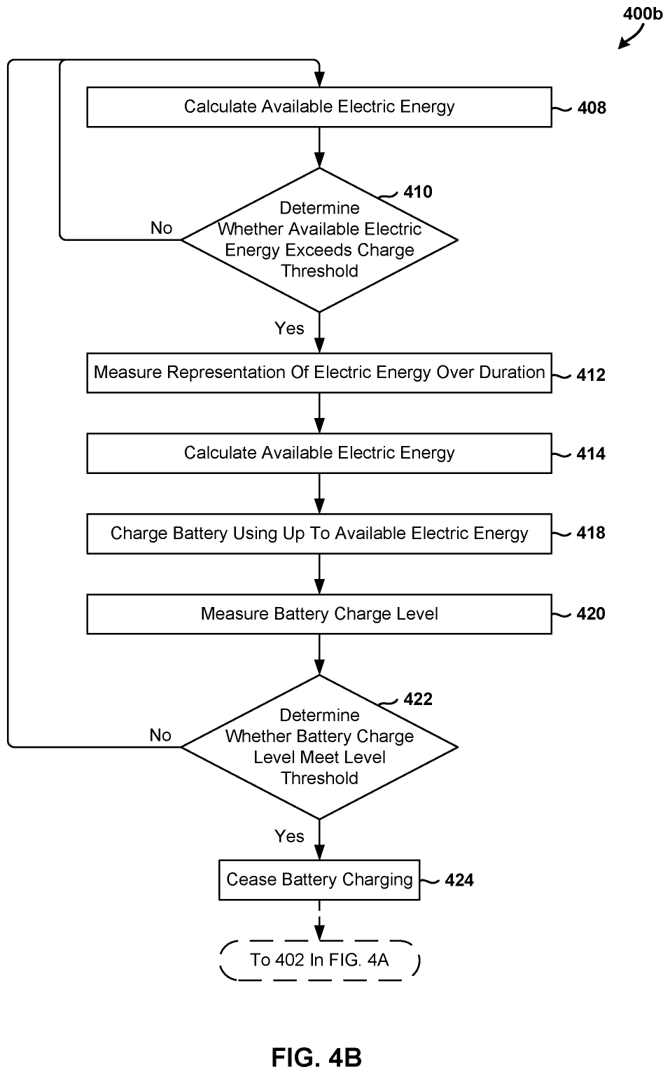

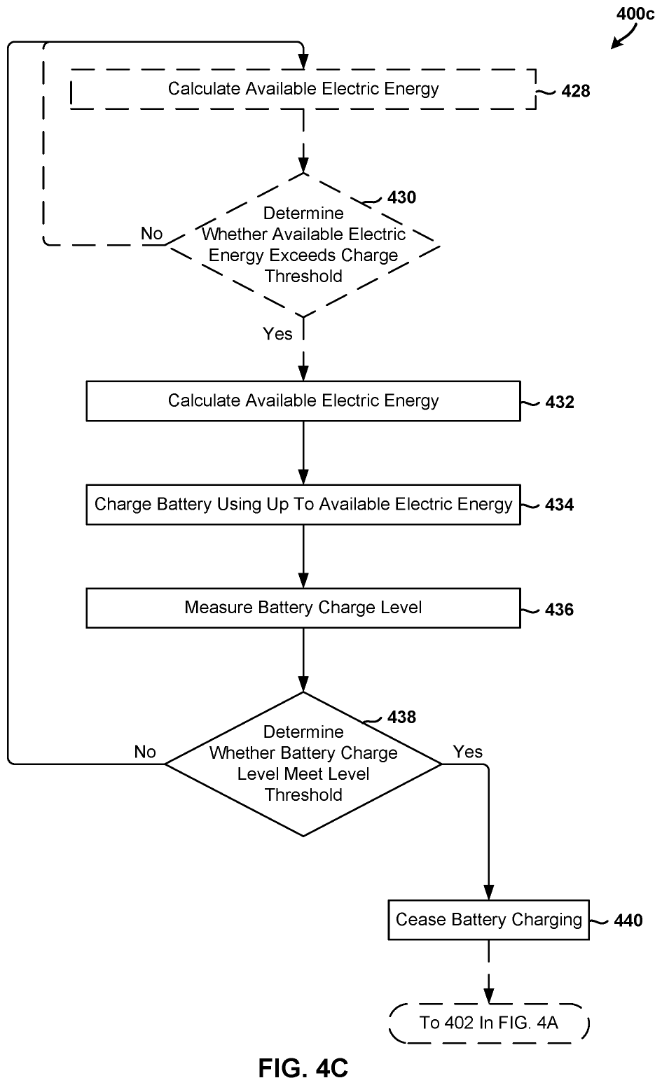

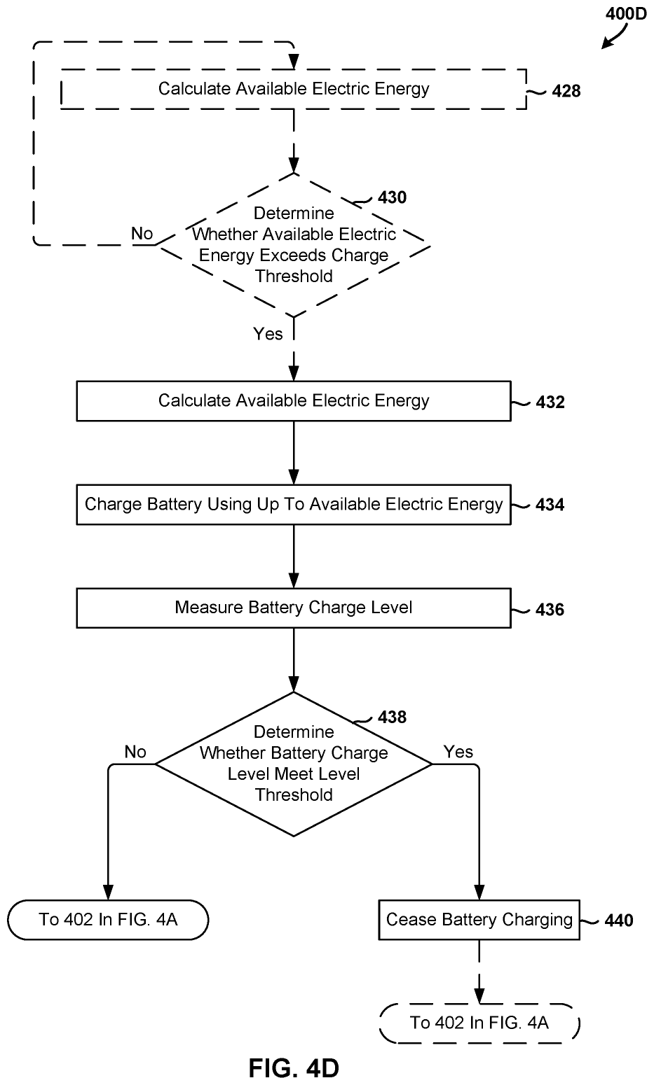

FIGS. 4A-4D illustrate methods 400a, 400b, 400c, 400d for implementing charging a battery 306 of a CPE 110 in accordance with the various embodiments. In some embodiments, the methods 400a, 400b, 400c, 400d may be accomplished with one or more additional operations not described, and/or without one or more of the operations discussed. Additionally, the order in which the operations of methods 400a, 400b, 400c, 400d are illustrated in FIGS. 4A-4D and described below is not intended to be limiting.

In some embodiment, methods 400a, 400b, 400c, 400d may be implemented in a processing system 314, having one or more processors, in conjunction with memory (e.g., processing system-readable medium 316, memory 318 in FIG. 3B). The processing system 314 may include one or more device(s) executing some or all of the operations of the methods 400a, 400b, 400c, 400d in response to instructions (e.g., charger modules 320-328 in FIG. 3B) stored electronically on an electronic storage medium (e.g., processing system-readable medium 316 in FIG. 3B). The processing system 314 may include one or more devices configured through hardware, firmware, and/or software to be specifically designed for execution of one or more of the operations of the methods 400a-400d. For example, with reference to FIGS. 1-4D, the operations of the methods 400a-400d may be performed by the processing system 314 of the charger 304 of the CPE 110.

With reference to FIG. 4A, in block 402, the processing system 314 may measure an electric energy usage of the CPE 110. The processing system 314 may be configured to receive an electric energy measurement signal configured to indicate to the processing system 314 an amount of electric energy usage by the CPE 110. The electric energy signal may be based on electric energy sensed or received at hardware (e.g., resistors, transistors, capacitors, inductors, etc.) of the CPE 110 configured as an electric energy measuring circuit. The hardware of the CPE 110 may receive or sense electric energy at one or more electrical connectors (e.g., electrical connectors 310, 312a, 312b in FIG. 3A) and output an electric energy measurement signal to the processing system 314. The processing system 314 may receive one or more electric energy measurement signals periodically, continuously, or episodically. The processing system 314 may interpret the electric energy measurement signal or use the electric energy measurement signal in operations to determine the electric energy usage of the CPE 110. In some embodiments, the processing system 314 may periodically, continuously, or episodically implement measuring the electric energy usage of the CPE 110 in block 402. For example, the processing system 314 may implement measuring the electric energy usage of the CPE 110 in block 402 prior to, following, or in parallel with any of blocks 404-440 of the methods 400a-400 described herein with reference to FIGS. 4A-4C.

In determination block 404, the processing system 314 may determine whether the electric energy usage exceeds an idle threshold. The CPE 110 may use at most a certain amount of electric energy operating in an idle mode. The certain amount of electric energy used by the CPE 110 operating in an idle mode is less than an amount of electric energy used by the CPE 110 operating in an active mode. The CPE 110 using more than the certain amount of electric energy may be indicative to the processing system 314 that the CPE 110 is operating in the active mode. In some embodiments, the idle threshold may be a value representative of the certain amount of electric energy used by the CPE 110 operating in the idle mode. The measured electric energy usage of the CPE 110 may be compared to the idle threshold by the processing system 314. The measured electric energy usage of the CPE 110 exceeding the idle threshold may be indicative to the processing system 314 that the CPE 110 is not operating in the idle mode but rather is operating in the active mode.

Similarly, the CPE 110 may use at least a certain amount of electric energy operating in the active mode. The CPE 110 using less than the certain amount of electric energy may be indicative to the processing system 314 that the CPE 110 is operating in the idle mode. In some embodiments, the idle threshold (or alternatively referred to as an active threshold) may be a value representative of the certain amount of electric energy used by the CPE 110 operating in the active mode. The measured electric energy usage of the CPE 110 may be compared to the idle threshold by the processing system 314. The measured electric energy usage of the CPE 110 equaling or exceeding the idle threshold may be indicative to the processing system 314 that the CPE 110 is not operating in the idle mode but rather is operating in the active mode. Put another way, embodiments may use either a threshold indicative of the idle mode or the active mode in the determination block 404. In embodiments in which the threshold is indicative of the active mode, determination block 404 may determine whether electric energy usage exceeds the active threshold. For ease of discussion, the embodiment in which the idle threshold is used is described herein below. One of skill in the art would understand how to implement the active threshold.

In response to determining that the measured electric energy usage of the CPE 110 exceeds the idle threshold (i.e., determination block 404=“Yes”), the processing system 314 may implement block 408 of the method 400b described herein with reference to FIG. 4B. In response to determining that the measured electric energy usage of the CPE 110 does not exceed the idle threshold (i.e., determination block 404=“No”), the processing system 314 may implement block 432 (or optional block 428, 430) of the method 400c or 400d described herein with reference to FIGS. 4C or 4D.

The following table 1 includes a non-exhaustive and non-limiting list of examples of the CPE 110 conditions in an active mode and an idle mode. In some examples, the CPE 110 may be in the active mode for any of the low throughput, medium throughput, or high throughput traffic loads:

TABLE 1

| Traffic | | Current | |
|---|---|---|---|
| Load | Test Condition | (Maximum)/A | Notes |
| High | DS 8.9G/US 3.4G + | 3.14 | Each FXS ports with 5 REN |
| Throughput | 10 Ringer Equivalent | | ringing at the same time |
| | Number (REN) Ring | | |
| | DS 8.9G/US 3.4G + | 2.98 | Each FXS ports with 4 REN |
| | 8 REN Ring | | ringing at the same time |
| | DS 8.9G/US 3.4G + | 2.66 | One FXS port is ringing with |
| | 5 REN Ring | | 5 REN, and the other FXS |
| | | | port is off-hook. |
| | DS 8.9G/US 3.4G + | 2.571 | One FXS port is ringing with |
| | 4 REN Ring | | 4 REN, and the other FXS |
| | | | port is off-hook. |
| | DS 8.9G/US 3.4G + | 2.206 | Two FXS ports are on-hook. |
| | On Hook | | |
| | DS 8.9G/US 3.4G + | 2.405 | Two FXS ports are off-hook. |
| | Off Hook | | |
| Middle | DS 1.0G/US 0.5G + | 2.47 | One FXS port is ringing with |
| Throughput | 5 REN Ring | | 5 REN, and the other FXS |
| | | | port is off-hook. |
| | DS 1.0G/US 0.5G + | 2.013 | Two FXS ports are on-hook. |
| | On Hook | | |
| | DS 1.0G/US 0.5G + | 2.241 | Two FXS ports are off-hook. |
| | Off Hook | | |
| Low | DS 100M/US 40M + | 2.196 | One FXS port is ringing with |
| Throughput | 5 REN Ring | | 5 REN, and the other FXS |
| | | | port is off-hook. |
| | DS 100M/US 40M + | 1.719 | Two FXS ports are on-hook. |
| | On Hook | | |
| | DS 100M/US 40M + | 1.948 | Two FXS ports are off-hook. |
| | Off Hook | | |
| | Standby (Online | 1.302 | Idle state with two FXS ports |
| | Only) | | on-hook |

With reference to FIG. 4B, in response to determining that the measured electric energy usage of the CPE 110 exceeds the idle threshold (i.e., determination block 404 in FIG. 4A=“Yes”), the processing system 314 may calculate an available electric energy from the PSU 208 in block 408. In some instances, the PSU 208 may be able to provide the CPE 110 with more electrical energy than is currently being used by the CPE 110 (i.e., amount of electric energy usage by the CPE 110). The available electric energy from the PSU 208 may be an amount of electric energy that may be provided by the PSU 208 greater than the amount of electric energy usage by the CPE 110. In some embodiments, the amount of electric energy that may be provided by the PSU 208 may be known to the processing system 314 based on an energy rating of the PSU 208. The processing system 314 may retrieve the energy rating of the PSU 208 from the memory 318. In some embodiments, the amount of electric energy usage by the CPE 110 may be the measured electric energy usage of the CPE 110. In some embodiments, the amount of electric energy usage by the CPE 110 may be the measured electric energy usage of the CPE 110 at a discreet time. For example, the discreet time may be an instantaneous time of an instantaneous time-sampling technique. In some embodiments, the amount of electric energy usage by the CPE 110 may be the representation of the electric energy usage by the CPE 110 over a duration.

The available electric energy from the PSU 208 may be a result of a comparison of the amount of electric energy that may be provided by the PSU 208 and the amount of electric energy usage by the CPE 110. For example, the available electric energy from the PSU 208 may be the result of a difference of the amount of electric energy that may be provided by the PSU 208 and the amount of electric energy usage by the CPE 110. The available electric energy from the PSU 208 may be available for charging the battery 306. In some embodiments, the calculated available electric energy from the PSU 208 may be referred to as a first available electric energy or a second available electric energy.

In determination block 410, processing system 314 may determine whether the available electric energy from the PSU 208 exceeds a charge threshold. The electric energy from the PSU 208 is used by the CPE 110 to support the critical functions and charge the battery 306 of the CPE 110. Charging the battery 306 may require a minimum share of electric energy from the PSU 208. In some instances, the electric energy usage by the CPE 110 to support the critical functions may exceed an amount that would enable the PSU 208 to provide sufficient electric energy to charge the battery 306. In some instances, the electric energy usage by the CPE 110 to support the critical functions may be an amount low enough to enable the PSU 208 to provide sufficient electric energy to charge the battery 306. The charge threshold may be a value representative of the minimum amount of electric energy from the PSU 208 sufficient to charge the battery 306. For example, the available electric energy from the PSU 208 may be based on an amount of electric energy usage by the CPE 110 for maximum upstream and downstream throughputs and with an FXS port ringing event. The available electric energy from the PSU 208 may be compared to the charge threshold by the processing system 314. The available electric energy from the PSU 208 exceeding the charge threshold may be indicative to the processing system 314 that there is sufficient electric energy available from the PSU 208 to charge the battery 306. The available electric energy from the PSU 208 not exceeding the charge threshold may be indicative to the processing system 314 that there is insufficient electric energy available from the PSU 208 to charge the battery 306.

In response to determining that the available electric energy from the PSU 208 does not exceed the charge threshold (i.e., determination block 410=“No”), the processing system 314 may repeat calculating an available electric energy from the PSU 208 in block 408. As discussed herein, the processing system 314 may periodically, continuously, or episodically implement measuring the electric energy usage of the CPE 110 in block 402. Changes in the measured electric energy usage of the CPE 110 may result in a different outcome of calculating an available electric energy from the PSU 208 in block 408. For example, while the battery 306 is being charged, the CPE 110 may switch from low or medium upstream and downstream throughput to high or maximum upstream and downstream throughput with two FXS ports off-hook. The change in the CPE 110 operation may cause the charging process of battery 306 to be paused due to lack of sufficient electric energy from the PSU 208 to charge the battery 306. Charging the battery 306 may resume in response to the CPE 110 switching to operating with low or medium upstream and downstream throughputs.

In response to determining that the available electric energy from the PSU 208 exceeds the charge threshold (i.e., determination block 410=“Yes”), the processing system 314 may measure a representation (e.g., an average, a mean, Root-Mean-Square, etc.) of the electric energy usage by the CPE 110 over a duration in block 412. In some embodiments, the electric energy usage by the CPE 110 may be instantaneous electric energy usage by the CPE 110 measured at various points over the duration. The processing system 314 may periodically, continuously, or episodically measure the electric energy usage of the CPE 110, similarly as described in block 402, for a duration. In some embodiments, the duration may be any amount of time, such as less than a second, a second, or more than a second (e.g., approximately 2 seconds, 5 second, 10 seconds, 30 seconds, 60 seconds, 90 seconds, 300 seconds, etc.). The processing system 314 may calculate the representation of the electric energy usage by the CPE 110 measured over the duration.

In block 414, the processing system 314 may calculate an available electric energy from the PSU 208. The processing system 314 may calculate an available electric energy from the PSU 208 similarly as described herein for block 408. The available electric energy from the PSU 208 may be a result of a comparison of the amount of electric energy that may be provided by the PSU 208 and the amount of electric energy usage by the CPE 110. In some embodiments, the processing system 314 may calculate an available electric energy from the PSU 208 using the representation of the electric energy usage by the CPE 110 over the duration. For example, the available electric energy from the PSU 208 may be the result of a difference of the amount of electric energy that may be provided by the PSU 208 and the representation of the electric energy usage by the CPE 110 over the duration. The available electric energy from the PSU 208 may be available for charging the battery 306. In some embodiments, the calculated available electric energy from the PSU 208 may be referred to as a first available electric energy or a second available electric energy.

In block 418, the processing system 314 may charge the battery 306 using up to the available electric energy from the PSU 208. For various reasons, such as battery health, battery longevity, safety, regulation, etc., the amount of electric energy used to charge the battery 306 may be limited. Charging the battery 306 may be implemented using an amount of electric energy less than or equal to the available electric energy from the PSU 208. The processing system 314 may control when and how much electric energy of the available electric energy from the PSU 208 is used to charge the battery 306.

In block 420, the processing system 314 may measure a battery charge level. The processing system 314 may receive an electric energy measurement signal configured to indicate to the processing system 314 an amount of electric energy stored at the battery 306. The electric energy signal may be based on electric energy sensed or received at hardware (e.g., resistors, transistors, capacitors, inductors, etc.) of the CPE 110 configured as an electric energy measuring circuit. The hardware of the CPE 110 may receive or sense electric energy at one or more electrical connectors 312a, 312b and output an electric energy measurement signal to the processing system 314. The processing system 314 may interpret or use the electric energy measurement signal in operations to determine the battery charge level. The processing system 314 may receive one or more electric energy measurement signals periodically, continuously, or episodically. In some embodiments, the processing system 314 may periodically, continuously, or episodically implement measuring the battery charge level in block 420.

In determination block 422, the processing system 314 may determine whether the battery charge level equals a level threshold. The level threshold may be a value representative of a charge level for a fully charged battery 306. The processing system 314 may compare the measured battery charge level to the level threshold to determine whether battery charging has completed. The measured battery charge level being less than the level threshold may indicate to the processing system 314 that the battery 306 is not fully charged and that battery charging has not completed. The measured battery charge level equaling the level threshold may indicate to the processing system 314 that the battery 306 is fully charged and that battery charging has completed.

In response to determining that the battery charge level does not equal the level threshold (i.e., determination block 422=“No”), the processing system 314 may repeat calculating an available electric energy from the PSU 208 in block 408. As discussed herein, the processing system 314 may periodically, continuously, or episodically implement measuring the electric energy usage of the CPE 110 in block 402. Changes in the measured electric energy usage may result in a different outcome of calculating an available electric energy from the PSU 208 in block 408. In response to determining that the battery charge level equals the level threshold (i.e., determination block 422=“Yes”), the processing system 314 may cease battery charging in block 424. In some embodiments, the processing system 314 may optionally repeat measuring the electric energy usage of the CPE 110 in block 402. In some embodiments, repeating measuring the electric energy usage of the CPE 110 in block 402 may be implemented periodically or episodically.

With reference to FIG. 4C, optional block 428 and optional determination block 430 may be implemented by the CPE 110 operating in the idle mode that may be in a power save mode or may be powered down. In response to determining that the measured electric energy usage of the CPE 110 does not exceed the idle threshold (i.e., determination block 404 in FIG. 4A=“No”), the processing system 314 may calculate an available electric energy from the PSU 208 in optional block 428. In some instances, the PSU 208 may be able to provide the CPE 110 with more electrical energy than is currently being used by the CPE 110 (i.e., amount of electric energy usage by the CPE 110). The available electric energy from the PSU 208 may be an amount of electric energy that may be provided by the PSU 208 greater than the amount of electric energy usage by the CPE 110. In some embodiments, the amount of electric energy that may be provided by the PSU 208 may be known to the processing system 314 based on an energy rating of the PSU 208. The processing system 314 may retrieve the energy rating of the PSU 208 from the memory 318. In some embodiments, the amount of electric energy usage by the CPE 110 may be the measured electric energy usage of the CPE 110. In some embodiments, the amount of electric energy usage by the CPE 110 may be the measured electric energy usage of the CPE 110 at a discreet time. In some embodiments, the amount of electric energy usage by the CPE 110 may be the representation of the electric energy usage by the CPE 110 over a duration.

The available electric energy from the PSU 208 may be a result of a comparison of the amount of electric energy that may be provided by the PSU 208 and the amount of electric energy usage by the CPE 110. For example, the available electric energy from the PSU 208 may be the result of a difference of the amount of electric energy that may be provided by the PSU 208 and the amount of electric energy usage by the CPE 110. The available electric energy from the PSU 208 may be available for charging the battery 306. In some embodiments, the calculated available electric energy from the PSU 208 may be referred to as a first available electric energy or a second available electric energy.

In optional determination block 430, the processing system 314 may determine whether the available electric energy from the PSU 208 exceeds a charge threshold. The electric energy from the PSU 208 is used by the CPE 110 to support the critical functions and charge the battery 306 of the CPE 110. Charging the battery 306 may require a minimum share of electric energy from the PSU 208. In some instances, the electric energy usage by the CPE 110 to support the critical functions may exceed an amount that would enable the PSU 208 to provide sufficient electric energy to charge the battery 306. In some instances, the electric energy usage by the CPE 110 to support the critical functions may be an amount low enough to enable the PSU 208 to provide sufficient electric energy to charge the battery 306. The charge threshold may be a value representative of the minimum amount of available electric energy from the PSU 208 sufficient to charge the battery 306. For example, the available electric energy from the PSU 208 may be based on an amount of electric energy usage by the CPE 110. The CPE 110 operating in the idle mode may be in the power save mode or may be powered down. In the power save mode, the CPE 110 may be using electric energy from the battery 306 and may be able to make emergency calls to an emergency line, such as to “9-1-1.” The available electric energy from the PSU 208 may be compared to the charge threshold by the processing system 314. The available electric energy from the PSU 208 exceeding the charge threshold may be indicative to the processing system 314 that there is sufficient electric energy available from the PSU 208 to charge the battery 306. The available electric energy from the PSU 208 not exceeding the charge threshold may be indicative to the processing system 314 that there is insufficient electric energy available from the PSU 208 to charge the battery 306.

In response to determining that the available electric energy from the PSU 208 does not exceed the charge threshold (i.e., optional determination block 430=“No”), the processing system 314 calculating an available electric energy from the PSU 208 in optional block 428. As discussed herein, the processing system 314 may periodically, continuously, or episodically implement measuring the electric energy usage of the CPE 110 in block 402. Changes in the measured electric energy usage of the CPE 110 may result in a different outcome of calculating an available electric energy from the PSU 208 in optional block 428.

In response to determining that the measured electric energy usage of the CPE 110 does not exceed the idle threshold (i.e., determination block 404 in FIG. 4A=“No”); or in response to determining that the available electric energy from the PSU 208 exceeds the charge threshold (i.e., optional determination block 430=“Yes”), the processing system 314 may calculate an available electric energy from the PSU 208 in block 432. In some instances, the PSU 208 may be able to provide the CPE 110 with more electrical energy than is currently being used by the CPE 110 (i.e., amount of electric energy usage by the CPE 110). The available electric energy from the PSU 208 may be an amount of electric energy that may be provided by the PSU 208 greater than the amount of electric energy usage by the CPE 110. In some embodiments, the amount of electric energy that may be provided by the PSU 208 may be known to the processing system 314 based on an energy rating of the PSU 208. The processing system 314 may retrieve the energy rating of the PSU 208 from the memory 318. In some embodiments, the amount of electric energy usage by the CPE 110 may be known to the processing system 314 based on an idle mode electric energy usage by the CPE 110. The processing system 314 may retrieve the idle mode electric energy usage by the CPE 110 from the memory 318. In some embodiments, the amount of electric energy usage by the CPE 110 may be the measured electric energy usage of the CPE 110 at a discreet time. In some embodiments, the amount of electric energy usage by the CPE 110 may be the representation of the electric energy usage by the CPE 110 over the duration.

The available electric energy from the PSU 208 may be a result of a comparison of the amount of electric energy that may be provided by the PSU 208 and the amount of electric energy usage by the CPE 110. For example, the available electric energy from the PSU 208 may be the result of a difference of the amount of electric energy that may be provided by the PSU 208 and the amount of electric energy usage by the CPE 110. The available electric energy from the PSU 208 may be available for charging the battery 306. In some embodiments, the calculated available electric energy from the PSU 208 may be referred to as a first available electric energy or a second available electric energy.

In block 434 the processing system 314 may charge the battery 306 using up to the available electric energy from the PSU 208. For various reasons, such as battery health, battery longevity, safety, regulation, etc., the amount of electric energy used to charge the battery 306 may be limited. Charging the battery 306 may be implemented using an amount of electric energy less than or equal to the available electric energy from the PSU 208. The processing system 314 may control when and how much electric energy of the available electric energy from the PSU 208 is used to charge the battery 306.

In block 436, the processing system 314 may measure a battery charge level. The processing system 314 may receive an electric energy measurement signal configured to indicate to the processing system 314 an amount of electric energy stored at the battery 306. The electric energy signal may be based on electric energy sensed or received at hardware (e.g., resistors, transistors, capacitors, inductors, etc.) of the CPE 110 configured as an electric energy measuring circuit. The hardware of the CPE 110 may receive or sense electric energy at one or more electrical connectors 312a, 312b and output an electric energy measurement signal to the processing system 314. The processing system 314 may interpret or use the electric energy measurement signal in operations to determine the battery charge level. The processing system 314 may receive one or more electric energy measurement signals periodically, continuously, or episodically. In some embodiments, the processing system 314 may periodically, continuously, or episodically implement measuring the battery charge level in block 436.

In determination block 438, the processing system 314 may determine whether the battery charge level equals a level threshold. The level threshold may be a value representative of a charge level for a fully charged battery 306. The processing system 314 may compare the measured battery charge level to the level threshold to determine whether battery charging has completed. The measured battery charge level being less than the level threshold may indicate to the processing system 314 that the battery 306 is not fully charged and that battery charging has not completed. The measured battery charge level equaling the level threshold may indicate to the processing system 314 that the battery 306 is fully charged and that battery charging has completed.

In some embodiments, in response to determining that the battery charge level does not equal the level threshold (i.e., determination block 438=“No”), the processing system 314 may optionally repeat calculating an available electric energy from the PSU 208 in optional block 428. In response to determining that the battery charge level equals the level threshold (i.e., determination block 438=“Yes”), the processing system 314 may cease battery charging in block 440. In some embodiments, the processing system 314 may optionally repeat measuring the electric energy usage of the CPE 110 in block 402. In some embodiments, repeating measuring the electric energy usage of the CPE 110 in block 402 may be implemented periodically or episodically.

With reference to FIG. 4D, optional blocks 428 and 430 and blocks 432-440 may be implemented in a manner similar to optional blocks 428 and 430 and blocks 432-440 of the method 400c described herein with reference to FIG. 4C unless otherwise described herein. In response to determining that the battery charge level does not equal the level threshold (i.e., determination block 438=“No”), the processing system 314 may repeat measuring the electric energy usage of the CPE 110 in block 402 of FIG. 4A. In some embodiments, repeating measuring the electric energy usage of the CPE 110 in block 402 may be alternative to or in addition to repeating calculating an available electric energy from the PSU 208 block 428, 432 in the method 400c described herein with reference to FIG. 4C. In some embodiments, repeating measuring the electric energy usage of the CPE 110 in block 402 may be implemented periodically or episodically. For example, repeating measuring the electric energy usage of the CPE 110 in block 402 may be triggered by a change in available electric energy from the PSU 208 indicating a change in operating mode of the CPE 110, such as from an idle mode to an active mode.

FIGS. 5A and 5B illustrate examples of the CPE 110 connected to a remote monitoring device 500 suitable for use with various embodiments. With reference to FIGS. 1-5B, the CPE 110 and the components of the CPE 110 may be configured as described herein. The components of the CPE 110 may include the SoC 202, the battery module 204, the one or more communication interfaces 206, the PSU 208, the electrical interface 210, the electrical connectors 220, 222, 226, and the one or more communication buses 224.

The battery module 204 and the processing system 214 may be connected via a communication link 510, which may be wired or wireless. The communication link 510 may enable the processing system 214 to receive battery status information from the battery module 204. For example, the battery status information may relate to the battery 306 and may be transmitted to the processing system 214 of the CPE 110 by the processing system 314 of the charger 304. The communication link 510 may enable the processing system 214 to transmit battery charge commands to the battery module 204. For example, the battery charge commands may relate to the battery 306 and may be transmitted to the processing system 314 of the charger 304 by the processing system 214 of the CPE 110.

The processing system 214 of the CPE 110 may be configured with processor-executable instructions, such as software or firmware instructions, to implement an operating system. A non-exhaustive and non-limiting list of examples of the operating system may include a Linux based operating system, proprietary operating system, commercial operating system, open-source operating system, OpenWrt, prplOS, etc. The processing system 214 may implement, via the operating system, functions of a software that may enable the CPE 110 to access cloud-based services. A non-exhaustive and non-limiting list of examples of the software may include OpenSync, Cujo AI, EasyMesh, etc. For example, the processing system 214 may implement battery simple network management protocol (SNMP) management information base (MIB) functions. A non-exhaustive and non-limiting list of examples of the SNMP MIB functions for the battery 306 may include: upsIdentManufacturer; upsIdentModel; upsIdentAgentSoftware Version; upsBatteryStatus; upsSecondsOnBattery; upsEstimatedChargeRemaining; upsAlarmsPresent; upsAlarmDescr-upsAlarmOnBattery; upsAlarmDescr-upsAlarmLowBattery; upsAlarmDescr-upsAlarmDepletedBattery; upsReboot WithDuration; upsOutput Voltage; upsAlarmsPresent; upsAlarmDescr-upsAlarmShutdownPending; upsAlarmDescr-upsAlarmShutdownImminent; upsConfigLowBattTime; upsConfigAudibleStatus; mtaDevPwrSupplyBatteryTest; mtaDevPwrSupplyConfigReplaceBatteryTime; mtaDevPwrSupplyBatteryTestTime; upsIdentName; upsIdentAttachedDevices; upsEstimatedMinutesRemaining; upsAlarmDescr-upsAlarmBatteryBad; upsAlarmDescr-upsAlarmOutputOffAsRequested; upsAlarmDescr-upsAlarmUpsOutputOff; upsAlarmDescr-upsAlarmGeneralFault; upsAlarmDescr-upsAlarmAwaitingPower; upsShutdownType; upsShutdownAfterDelay; upsEstimatedMinutesRemaining; mtaDevPwrSupplyRatedMinutes; mtaDevPwrSupplyAvailableMinutes; mtaDevPwrSupplyFullChargeTime; mtaDevPwrSupplyConfigRunTime etc.

The processing system 214 may be connected to a remote monitoring device 500 (e.g., computing device 150 in FIG. 1) via the one or more communication interfaces 206 and a communication link 502 (e.g., communication link 137, communication network 140, network operations sites 142, 144, 146 in FIG. 1). In some embodiments, the remote monitoring device 500 may be located at a communication network (e.g., communication network 140 in FIG. 1), such as part of a cloud computing network. The cloud computing network may include multiple remote monitoring devices 500 configured to, individually or together, implement cloud-based services accessible by the CPE 110. The remote monitoring device 500 may include a processing system 504, communication systems, and memory configured to implement cloud-based services configured for remote battery charging monitoring and control. The processing system 504 may include one or more processors, processor cores, controllers, microcontrollers, etc.

The processing system 214 of the CPE 110 may implement functions for transmitting battery status (or telemetry) information for the battery module 204 from the CPE 110 to the remote monitoring device 500. The processing system 214 may transmit the battery status information to the remote monitoring device 500 continuously, periodically, or episodically. In some embodiments, transmitting the battery status information may include streaming the battery status information. The battery status information may include charge data for the battery 306, such as a level of charge of the battery 306. Other examples of charge data for the battery 306 may include time or date of battery charging, low-battery alarm, depleted battery alarm, duration of battery charging, etc. Other examples of battery status information may include battery type, battery size, battery manufacturer, battery model, battery hardware version, battery firmware version, battery manufacture date, battery expiration date, etc.

The processing system 504 of the remote monitoring device 500, executing software processor-executable instructions (e.g., Grafana, SigNoz, Kibana, etc.), may be configured to monitor the battery status information for the battery module 204. The processing system 504, executing the software processor-executable instructions, may provide the battery status information or representations of the information (e.g., raw data, analyzed data, pictorial/graphical data, etc.) to a monitoring entity (e.g., a dashboard). The processing system 504, executing the software processor-executable instructions, may be configured to present, analyze, or respond to the battery status information for the battery module 204.

In some examples, the processing system 504 may respond to the battery status information for the battery module 204 based on one or more criterion. The response to the battery status information may include commands to cause the processing system 214 of the CPE 110 to prompt the battery module 204 to implement battery charging functions. For example, the processing system 504 may determine that the battery charge capacity is depleted or the one or more batteries are not being charged. Based on the determination, the processing system 504 may raise an alarm, such as via the monitoring entity. The processing system 504 may transmit a command to the CPE 110 to reboot, such as via the upsRebootDuration MIB.

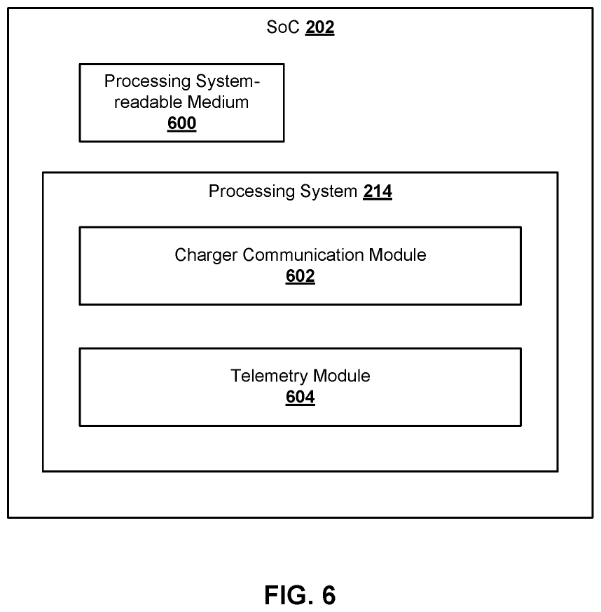

FIG. 6 illustrates an example of the SoC 202 of the CPE 110 suitable for use with various embodiments. With reference to FIGS. 1-6, the SoC 202 may include the processing system 214 configured with software or firmware processor-executable instructions, for implementing functions of battery status information telemetry. The processing system 214 may include one or more processors, processor cores, controllers, microcontrollers, etc. Such functions of battery status information telemetry may include any combination of controlling receiving and transmitting battery status information, receiving and transmitting battery charge commands, etc. In some embodiments, the software or firmware processor-executable instructions may be configured as modules, including a charger communication module 602 and a telemetry module 604. The software or firmware, including the modules 602, 604, for implementing the functions of battery status information telemetry may be stored on and accessed by the processing system 214 from a processing system-readable medium 600. The processing system-readable medium 600 may include one or more of a non-volatile memory, volatile memory, main memory, cache memory, etc.

The processing system 214, implementing the charger communication module 602, may receive battery status information from the charger 304. For example, the processing system 214 may receive the battery status information from the processing system 314 of the charger 304. For another example, the processing device 214 may retrieve the battery status information from the processing system-readable medium 316 or the memory 318. The processing system 214, implementing the telemetry module 602, may transmit battery status information to the remote monitoring device 500. In some embodiments, the processing system 214, implementing the telemetry module 602, may receive battery charging commands from the remote monitoring device 500. In some embodiments, the processing system 214, implementing the charger communication module 602, may transmit the battery charging commands received from the remote monitoring device 500 to the processing system 314 of the charger 304.

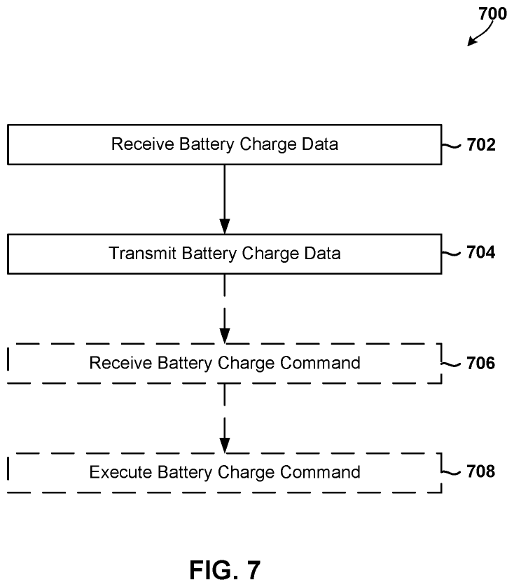

FIG. 7 illustrates a method 700 for implementing remote battery charging monitoring and control for the battery 306 of the CPE 110 in accordance with the various embodiments. In some embodiments, the method 700 may be accomplished with one or more additional operations not described, and/or without one or more of the operations discussed. Additionally, the order in which the operations of the method 700 are illustrated in FIG. 7 and described below is not intended to be limiting.

In some embodiment, the method 700 may be implemented in a processing system 214 of the CPE 110, having one or more processors, in conjunction with memory (e.g., processing system-readable medium 600 in FIG. 6). The processing system 214 may include one or more device(s) executing some or all of the operations of the method 700 in response to instructions (e.g., SoC modules 602, 604 in FIG. 6) stored electronically on an electronic storage medium (e.g., processing system-readable medium 600 in FIG. 6). The processing system 214 may include one or more devices configured through hardware, firmware, and/or software to be specifically designed for execution of one or more of the operations of the method 700. For example, with reference to FIGS. 1-7, the operations of the method 700 may be performed by the processing system 214 of the CPE 110.

In block 702, the processing system 214 may receive battery status information. For example, the battery status information may include charge data for the battery 306, such as a level of charge of the battery 306. The level of charge of the battery 306 may be the level of charge of the battery 306 measured in blocks 420, 436 of the methods 400b, 400c described herein with reference to FIGS. 4B and 4C. Other examples of battery charge data for the battery 306 may include time or date of battery charging, low-battery alarm, depleted battery alarm, duration of battery charging, etc. Other examples of battery status information may include battery type, battery size, battery manufacturer, battery model, battery hardware version, battery firmware version, battery manufacture date, battery expiration date, etc. In some embodiments, the processing system 214 may retrieve the battery status information from a memory (e.g., processing system-readable medium 316, 600, memory 318 in FIGS. 3B and 6). In some embodiments, the processing system 214 may receive the battery status information from a battery module 204, such as from the processing system 314 of the charger 304.

In block 704, the processing system 214 may transmit the battery status information to a remote monitoring device 500. The processing system 214 may transmit the battery status information via a communication interface 206. The battery status information may transmit via one or more communication links 502 (e.g., communication links 137, network operations sites 142, 144, 146, communication network 140 in FIG. 1). In some embodiments, the processing system 214 may implement an operating system (e.g., Linux based operating system, proprietary operating system, commercial operating system, open-source operating system, OpenWrt, prplOS, etc.). The processing system 214, via the operating system, may implement functions of a software (e.g., OpenSync, Cujo AI, EasyMesh, etc.). The functions of the software may enable the processing system 214 to access cloud-based services based on the transmitted battery status information. For example, the processing system 214 may implement battery SNMP MIB functions.

In optional block 706, the processing system 214 may receive a battery charge command from the remote monitoring device 600. The battery charge command may be configured to prompt the processing system 214 to implement aspects of battery charging. The aspects of battery charging may include charging the battery, setting battery charging parameters, rebooting battery charging software or firmware, etc. The processing system 214 may receive the battery charge command at the communication interface 206. The battery charge command may transmit via one or more of the communication links 502.

In optional block 708, the processing system 214 may execute the battery charge command. The processing system 214 may transmit the battery charge command to the processing system 314 of the charger 304. The processing system 314 may implement the battery charge command for the battery 306.

Various embodiments illustrated and described are provided merely as examples to illustrate various features of the claims. However, features shown and described with respect to any given embodiment are not necessarily limited to the associated embodiment and may be used or combined with other embodiments that are shown and described. Further, the claims are not intended to be limited by any one example embodiment. For example, one or more of the operations of the methods 400a-400c and 700 may be substituted for or combined with one or more operations of the methods 400a-400c and 700, and vice versa.

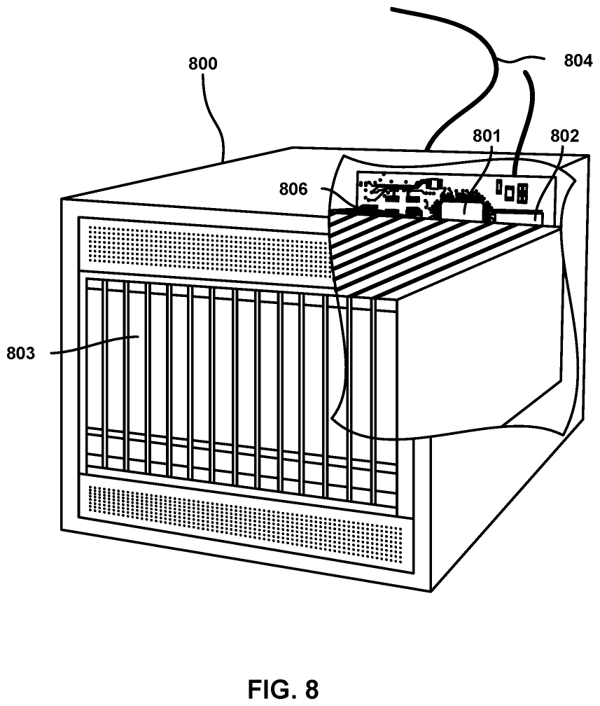

Various embodiments (including, but not limited to, embodiments discussed above with reference to FIGS. 1-7) may be implemented on any of a variety of commercially available computing devices, such as the server computing device 800 illustrated in FIG. 8. Such a server device 800 may include a processor 801 coupled to volatile memory 802 and a large capacity nonvolatile memory, such as a disk drive 803. The server device 800 may also include a floppy disc drive, USB, compact disc (CD) or DVD disc drive coupled to the processor 801. The server device 800 may also include network access ports 806 coupled to the processor 801 for establishing data connections with a network connection circuit 804 and a communication network (e.g., IP network) coupled to other communication system network elements.

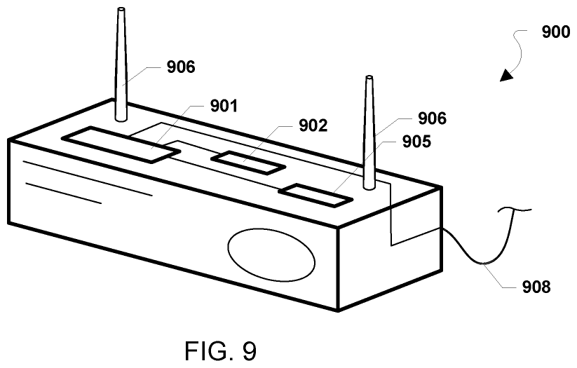

The various embodiments (including, but not limited to, embodiments discussed above with reference to FIGS. 1-7) may be implemented for any of a variety of network devices 900 (e.g., CPE 110, network hardware 142, 144, 146 in FIGS. 1-2B, 5A, and 5B), as illustrated in FIG. 9. With reference to FIGS. 1-9, a network device 900 may include a processor 901 coupled to volatile memory 902. The network device 900 may also include one or more connections or port(s) 908 coupled to the processor 901 and configured to input or output data from the port(s) 908. The network device 900 may also include one or more network transceivers 905, with one or more antenna 906 coupled thereto, providing a network access port, coupled to the processor 901 for establishing wired or wireless network interface connections with a communication network, such as a local area network coupled to other computing devices and routers/switches, the Internet, the public switched telephone network, or a cellular network (e.g., CDMA, TDMA, GSM, PCS, 3G, 4G, 5G, LTE, or any other type of cellular network). The network device 900 may transmit or receive data or other communications via the network transceiver 905 or the port(s) 908.

Various embodiments illustrated and described are provided merely as examples to illustrate various features of the claims. However, features shown and described with respect to any given embodiment are not necessarily limited to the associated embodiment and may be used or combined with other embodiments that are shown and described. Further, the claims are not intended to be limited by any one example embodiment. For example, one or more of the methods and operations 400a, 400b, 400c, and 700 may be substituted for or combined with one or more operations of the methods and operations 400a, 400b, 400c, and 700.

Implementation examples are described in the following paragraphs. While some of the following implementation examples are described in terms of example methods, further example implementations may include: the example methods discussed in the following paragraphs implemented by a CPE including a battery and a processor configured with processor-executable instructions to perform operations of the methods of the following implementation examples; the example methods discussed in the following paragraphs implemented by a CPE including means for performing functions of the methods of the following implementation examples; and the example methods discussed in the following paragraphs may be implemented as a non-transitory processor-readable storage medium having stored thereon processor-executable instructions configured to cause a processor of a base station to perform the operations of the methods of the following implementation examples.

Example 1. A method performed by a processor of a CPE for performing charging of at least one battery of the CPE, including calculating available electric energy from a power supply unit (PSU) of the CPE, and charging the at least one battery of the CPE using the available electric energy from the PSU.

Example 2. The method of example 1, including measuring electric energy usage of the CPE, and determining whether the measured electric energy usage of the CPE exceeds an idle threshold, wherein calculating the available electric energy from the PSU comprises calculating the available electric energy from the PSU using a representation of electric energy usage of the CPE over a duration in response to determining that the electric energy usage at the CPE exceeds the idle threshold, and wherein calculating the available electric energy from the PSU comprises calculating the available electric energy from the PSU using an idle electric energy usage of the CPE in response to determining that the electric energy usage at the CPE does not exceed the idle threshold.

Example 3. The method of example 1, wherein calculating the available electric energy from the PSU includes calculating a first available electric energy from the PSU, the method further including: calculating a representation of electric energy usage of the CPE over a duration, and calculating a second available electric energy from the PSU of the CPE using the representation of electric energy usage of the CPE over the duration, wherein charging the at least one battery of the CPE using the available electric energy from the PSU comprises charging the at least one battery of the CPE using the second available electric energy from the PSU.

Example 4. The method of example 3, also including: measuring electric energy usage of the CPE, wherein calculating the first available electric energy from the PSU includes calculating the first available electric energy from the PSU using the measuring electric energy usage of the CPE; and determining whether the first available electric energy from the PSU exceeds a charge threshold, wherein calculating the second available electric energy from the PSU using the representation of electric energy usage of the CPE over the duration comprises calculating the second available electric energy from the PSU using the representation of electric energy usage of the CPE over the duration in response to determining that the first available electric energy from the PSU exceeds the charge threshold.

Example 5. The method of example 3, also including: determining whether the second available electric energy from the PSU exceeds an availability threshold, wherein charging the at least one battery of the CPE using the second available electric energy from the PSU comprises charging the at least one battery of the CPE using the second available electric energy from the PSU in response to determining that the available electric from the PSU exceeds the availability threshold.

Example 6. The method of example 1, wherein calculating the available electric energy from the PSU comprises calculating a first available electric energy from the PSU using an idle electric energy usage of the CPE.

Example 7. The method of example 6, also including: measuring electric energy usage of the CPE; calculating a second available electric energy from the PSU of the CPE using the measured electric energy usage of the CPE; and determining whether the second available electric energy from the PSU exceeds a charge threshold, wherein calculating the first available electric energy from the PSU using the idle electric energy usage of the CPE comprises calculating the first available electric energy from the PSU using the idle electric energy usage of the CPE in response to determining that the second available electric energy from the PSU exceeds the charge threshold.

Example 8. The method of example 1, wherein calculating the available electric energy from the PSU comprises calculating the available electric energy from the PSU using a value representative of electric energy usage at the CPE operating with maximum upstream and downstream data throughputs with a foreign exchange subscriber port ringing even, the method further including determining whether the available electric energy from the PSU exceeds a charge threshold.

Example 9. The method of example 1, further including streaming battery status information from the CPE to a remote monitoring device.

Example 10. The method of example 1, further including receiving, at the CPE, a battery charge command from a remote monitoring device, wherein charging the at least one battery of the CPE using the available electric energy from the PSU comprises charging the at least one battery of the CPE in response to receiving the battery charge command.

The processors discussed in this application may be any programmable microprocessor, microcomputer or multiple processor chip or chips that may be configured by software instructions (applications) to perform a variety of functions, including the functions of the various embodiments described above. In some devices, multiple processors may be provided, such as one processor dedicated to wireless communication functions and one processor dedicated to running other applications. Typically, software applications may be stored in the internal memory before they are accessed and loaded into the processors. The processors may include internal memory sufficient to store the application software instructions. In many devices, the internal memory may be a volatile or nonvolatile memory, such as flash memory, or a mixture of both. For the purposes of this description, a general reference to memory refers to memory accessible by the processors including internal memory or removable memory plugged into the device and memory within the processors themselves. Additionally, as used herein, any reference to a memory may be a reference to a memory storage and the terms may be used interchangeably.

The foregoing method descriptions and the process flow diagrams are provided merely as illustrative examples and are not intended to require or imply that the steps of the various embodiments must be performed in the order presented. As will be appreciated by one of skill in the art the order of steps in the foregoing embodiments may be performed in any order. Words such as “thereafter,” “then,” “next,” etc. are not intended to limit the order of the steps; these words are simply used to guide the reader through the description of the methods. Further, any reference to claim elements in the singular, for example, using the articles “a,” “an” or “the” is not to be construed as limiting the element to the singular.

The various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The hardware used to implement the various illustrative logics, logical blocks, modules, components, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Alternatively, some steps or methods may be performed by circuitry that is specific to a given function.

In one or more exemplary embodiments, the functions described may be implemented in hardware, software, firmware, or any combination thereof. If implemented in software, the functions may be stored as one or more instructions or code on a non-transitory computer-readable medium, non-transitory processor-readable medium, or non-transitory processor system-readable medium. The steps of a method or algorithm disclosed herein may be embodied in a processor-executable software module and/or processor-executable instructions, which may reside on a non-transitory computer-readable or non-transitory processor-readable storage medium. Non-transitory server-readable, computer-readable or processor-readable storage media may be any storage media that may be accessed by a computer or a processor. By way of example but not limitation, such non-transitory server-readable, computer-readable or processor-readable media may include RAM, ROM, EEPROM, FLASH memory, CD-ROM or other optical disk storage, magnetic disk storage or other magnetic storage devices, or any other medium that may be used to store desired program code in the form of instructions or data structures and that may be accessed by a computer. Disk and disc, as used herein, includes compact disc (CD), laser disc, optical disc, DVD, floppy disk, and Blu-ray disc where disks usually reproduce data magnetically, while discs reproduce data optically with lasers. Combinations of the above are also included within the scope of non-transitory server-readable, computer-readable and processor-readable media. Additionally, the operations of a method or algorithm may reside as one or any combination or set of codes and/or instructions on a non-transitory server-readable, processor-readable medium and/or computer-readable medium, which may be incorporated into a computer program product.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following claims and the principles and novel features disclosed herein.

What is claimed is:

1. A method for performing charging of at least one battery of a customer premises device (CPE), the method comprising:
calculating available electric energy from a power supply unit (PSU) of the CPE; and
charging the at least one battery of the CPE using the available electric energy from the PSU.

2. The method of claim 1, further comprising:
measuring electric energy usage of the CPE; and
determining whether the measured electric energy usage of the CPE exceeds an idle threshold,
wherein calculating the available electric energy from the PSU comprises calculating the available electric energy from the PSU using a representation of electric energy usage of the CPE over a duration in response to determining that the electric energy usage at the CPE exceeds the idle threshold, and
wherein calculating the available electric energy from the PSU comprises calculating the available electric energy from the PSU using an idle electric energy usage of the CPE in response to determining that the electric energy usage at the CPE does not exceed the idle threshold.

3. The method of claim 1, wherein calculating the available electric energy from the PSU comprises calculating a first available electric energy from the PSU,
the method further comprising:
calculating a representation of electric energy usage of the CPE over a duration; and
calculating a second available electric energy from the PSU of the CPE using the representation of electric energy usage of the CPE over the duration,
wherein charging the at least one battery of the CPE using the available electric energy from the PSU comprises charging the at least one battery of the CPE using the second available electric energy from the PSU.

4. The method of claim 3, further comprising:
measuring electric energy usage of the CPE, wherein calculating the first available electric energy from the PSU comprises calculating the first available electric energy from the PSU using the measuring electric energy usage of the CPE; and
determining whether the first available electric energy from the PSU exceeds a charge threshold,
wherein calculating the second available electric energy from the PSU using the representation of electric energy usage of the CPE over the duration comprises calculating the second available electric energy from the PSU using the representation of electric energy usage of the CPE over the duration in response to determining that the first available electric energy from the PSU exceeds the charge threshold.

5. The method of claim 1, wherein calculating the available electric energy from the PSU comprises calculating a first available electric energy from the PSU using an idle electric energy usage of the CPE.

6. The method of claim 5, further comprising:
measuring electric energy usage of the CPE;
calculating a second available electric energy from the PSU of the CPE using the measured electric energy usage of the CPE; and
determining whether the second available electric energy from the PSU exceeds a charge threshold,
wherein calculating the first available electric energy from the PSU using the idle electric energy usage of the CPE comprises calculating the first available electric energy from the PSU using the idle electric energy usage of the CPE in response to determining that the second available electric energy from the PSU exceeds the charge threshold.

7. The method of claim 1, wherein calculating the available electric energy from the PSU comprises calculating the available electric energy from the PSU using a value representative of electric energy usage at the CPE operating with maximum upstream and downstream data throughputs with a foreign exchange subscriber port ringing even,
the method further comprising determining whether the available electric energy from the PSU exceeds a charge threshold.

8. The method of claim 1, further comprising streaming battery status information from the CPE to a remote monitoring device.

9. The method of claim 1, further comprising receiving, at the CPE, a battery charge command from a remote monitoring device, wherein charging the at least one battery of the CPE using the available electric energy from the PSU comprises charging the at least one battery of the CPE in response to receiving the battery charge command.

10. A customer premises device (CPE) comprising a processing system configured with processing system-executable instructions to cause the processing system to perform operations, comprising:
calculating available electric energy from a power supply unit (PSU) of the CPE; and
charging at least one battery of the CPE using the available electric energy from the PSU.

11. The CPE of claim 10, wherein the processing system is configured with processing system-executable instructions to cause the processing system to perform operations further comprising:
measuring electric energy usage of the CPE; and
determining whether the measured electric energy usage of the CPE exceeds an idle threshold,
wherein calculating the available electric energy from the PSU comprises calculating the available electric energy from the PSU using a representation of electric energy usage of the CPE over a duration in response to determining that the electric energy usage at the CPE exceeds the idle threshold, and
wherein calculating the available electric energy from the PSU comprises calculating the available electric energy from the PSU using an idle electric energy usage of the CPE in response to determining that the electric energy usage at the CPE does not exceed the idle threshold.

12. The CPE of claim 10, wherein:
the processing system is configured with processing system-executable instructions to cause the processing system to perform operations such that calculating the available electric energy from the PSU comprises calculating a first available electric energy from the PSU; and
the processing system is configured with processing system-executable instructions to cause the processing system to perform operations further comprising:
calculating a representation of electric energy usage of the CPE over a duration; and
calculating a second available electric energy from the PSU of the CPE using the representation of electric energy usage of the CPE over the duration,
wherein charging the at least one battery of the CPE using the available electric energy from the PSU comprises charging the at least one battery of the CPE using the second available electric energy from the PSU.

13. The CPE of claim 12, wherein the processing system is configured with processing system-executable instructions to cause the processing system to perform operations further comprising:
measuring electric energy usage of the CPE, wherein calculating the first available electric energy from the PSU comprises calculating the first available electric energy from the PSU using the measuring electric energy usage of the CPE; and
determining whether the first available electric energy from the PSU exceeds a charge threshold,
wherein calculating the second available electric energy from the PSU using the representation of electric energy usage of the CPE over the duration comprises calculating the second available electric energy from the PSU using the representation of electric energy usage of the CPE over the duration in response to determining that the first available electric energy from the PSU exceeds the charge threshold.

14. The CPE of claim 10, wherein the processing system is configured with processing system-executable instructions to cause the processing system to perform operations such that calculating the available electric energy from the PSU comprises calculating a first available electric energy from the PSU using an idle electric energy usage of the CPE.

15. The CPE of claim 14, wherein the processing system is configured with processing system-executable instructions to cause the processing system to perform operations further comprising:
measuring electric energy usage of the CPE;
calculating a second available electric energy from the PSU of the CPE using the measured electric energy usage of the CPE; and
determining whether the second available electric energy from the PSU exceeds a charge threshold,
wherein calculating the first available electric energy from the PSU using the idle electric energy usage of the CPE comprises calculating the first available electric energy from the PSU using the idle electric energy usage of the CPE in response to determining that the second available electric energy from the PSU exceeds the charge threshold.

16. The CPE of claim 10, wherein:
the processing system is configured with processing system-executable instructions to cause the processing system to perform operations such that calculating the available electric energy from the PSU comprises calculating the available electric energy from the PSU using a value representative of electric energy usage at the CPE operating with maximum upstream and downstream data throughputs with a foreign exchange subscriber port ringing even; and
the processing system is configured with processing system-executable instructions to cause the processing system to perform operations further comprising determining whether the available electric energy from the PSU exceeds a charge threshold.

17. The CPE of claim 10, wherein the processing system is configured with processing system-executable instructions to cause the processing system to perform operations further comprising streaming battery status information from the CPE to a remote monitoring device.

18. The CPE of claim 10, wherein the processing system is configured with processing system-executable instructions to cause the processing system to perform operations further comprising receiving, at the CPE, a battery charge command from a remote monitoring device, wherein charging the at least one battery of the CPE using the available electric energy from the PSU comprises charging the at least one battery of the CPE in response to receiving the battery charge command.

19. A customer premises device (CPE), comprising:
means for calculating available electric energy from a power supply unit (PSU) of the CPE; and
means for charging at least one battery of the CPE using the available electric energy from the PSU.

20. The CPE of claim 19, further comprising:
means for measuring electric energy usage of the CPE; and
means for determining whether the measured electric energy usage of the CPE exceeds an idle threshold,
wherein means for calculating the available electric energy from the PSU comprises means for calculating the available electric energy from the PSU using a representation of electric energy usage of the CPE over a duration in response to determining that the electric energy usage at the CPE exceeds the idle threshold, and
wherein means for calculating the available electric energy from the PSU comprises means for calculating the available electric energy from the PSU using an idle electric energy usage of the CPE in response to determining that the electric energy usage at the CPE does not exceed the idle threshold.

21. The CPE of claim 19, wherein means for calculating the available electric energy from the PSU comprises means for calculating a first available electric energy from the PSU,
the CPE further comprising:
means for calculating a representation of electric energy usage of the CPE over a duration; and
means for calculating a second available electric energy from the PSU of the CPE using the representation of electric energy usage of the CPE over the duration,
wherein means for charging the at least one battery of the CPE using the available electric energy from the PSU comprises means for charging the at least one battery of the CPE using the second available electric energy from the PSU.

22. The CPE of claim 21, further comprising:
means for measuring electric energy usage of the CPE, wherein calculating the first available electric energy from the PSU comprises calculating the first available electric energy from the PSU using the measuring electric energy usage of the CPE; and
means for determining whether the first available electric energy from the PSU exceeds a charge threshold,
wherein means for calculating the second available electric energy from the PSU using the representation of electric energy usage of the CPE over the duration comprises means for calculating the second available electric energy from the PSU using the representation of electric energy usage of the CPE over the duration in response to determining that the first available electric energy from the PSU exceeds the charge threshold.

23. The CPE of claim 19, wherein means for calculating the available electric energy from the PSU comprises means for calculating a first available electric energy from the PSU using an idle electric energy usage of the CPE.

24. The CPE of claim 23, further comprising:
means for measuring electric energy usage of the CPE;
means for calculating a second available electric energy from the PSU of the CPE using the measured electric energy usage of the CPE; and
means for determining whether the second available electric energy from the PSU exceeds a charge threshold,
wherein means for calculating the first available electric energy from the PSU using the idle electric energy usage of the CPE comprises means for calculating the first available electric energy from the PSU using the idle electric energy usage of the CPE in response to determining that the second available electric energy from the PSU exceeds the charge threshold.

25. The CPE of claim 19, wherein means for calculating the available electric energy from the PSU comprises means for calculating the available electric energy from the PSU using a value representative of electric energy usage at the CPE operating with maximum upstream and downstream data throughputs with a foreign exchange subscriber port ringing even,
the CPE further comprising means for determining whether the available electric energy from the PSU exceeds a charge threshold.

26. The CPE of claim 19, further comprising means for streaming battery status information from the CPE to a remote monitoring device.

27. The CPE of claim 19, further comprising means for receiving, at the CPE, a battery charge command from a remote monitoring device, wherein charging the at least one battery of the CPE using the available electric energy from the PSU comprises charging the at least one battery of the CPE in response to receiving the battery charge command.

28. A non-transitory processing system-readable medium having stored thereon processing system-executable instructions configured to cause a processing system to perform operations comprising:
calculating available electric energy from a power supply unit (PSU) of the CPE; and
charging at least one battery of the CPE using the available electric energy from the PSU.

29. The non-transitory processor-readable medium of claim 28, wherein the stored processing system-executable instructions are configured to cause the processing system to perform operations further comprising:
measuring electric energy usage of the CPE; and
determining whether the measured electric energy usage of the CPE exceeds an idle threshold,
wherein calculating the available electric energy from the PSU comprises calculating the available electric energy from the PSU using a representation of electric energy usage of the CPE over a duration in response to determining that the electric energy usage at the CPE exceeds the idle threshold, and
wherein calculating the available electric energy from the PSU comprises calculating the available electric energy from the PSU using an idle electric energy usage of the CPE in response to determining that the electric energy usage at the CPE does not exceed the idle threshold.

30. The non-transitory processor-readable medium of claim 28, wherein:
the stored processing system-executable instructions are configured to cause the processing system to perform operations such that calculating the available electric energy from the PSU comprises calculating a first available electric energy from the PSU; and
the stored processing system-executable instructions are configured to cause the processing system to perform operations further comprising:
calculating a representation of electric energy usage of the CPE over a duration; and
calculating a second available electric energy from the PSU of the CPE using the representation of electric energy usage of the CPE over the duration,
wherein charging the at least one battery of the CPE using the available electric energy from the PSU comprises charging the at least one battery of the CPE using the second available electric energy from the PSU.

31. The non-transitory processor-readable medium of claim 30, wherein the stored processing system-executable instructions are configured to cause the processing system to perform operations further comprising:
measuring electric energy usage of the CPE, wherein calculating the first available electric energy from the PSU comprises calculating the first available electric energy from the PSU using the measuring electric energy usage of the CPE; and
determining whether the first available electric energy from the PSU exceeds a charge threshold,
wherein calculating the second available electric energy from the PSU using the representation of electric energy usage of the CPE over the duration comprises calculating the second available electric energy from the PSU using the representation of electric energy usage of the CPE over the duration in response to determining that the first available electric energy from the PSU exceeds the charge threshold.

32. The non-transitory processor-readable medium of claim 28, wherein the stored processing system-executable instructions are configured to cause the processing system to perform operations such that calculating the available electric energy from the PSU comprises calculating a first available electric energy from the PSU using an idle electric energy usage of the CPE.

33. The non-transitory processor-readable medium of claim 32, wherein the stored processing system-executable instructions are configured to cause the processing system to perform operations further comprising:
measuring electric energy usage of the CPE;
calculating a second available electric energy from the PSU of the CPE using the measured electric energy usage of the CPE; and
determining whether the second available electric energy from the PSU exceeds a charge threshold,
wherein calculating the first available electric energy from the PSU using the idle electric energy usage of the CPE comprises calculating the first available electric energy from the PSU using the idle electric energy usage of the CPE in response to determining that the second available electric energy from the PSU exceeds the charge threshold.

34. The non-transitory processor-readable medium of claim 28, wherein:
the stored processing system-executable instructions are configured to cause the processing system to perform operations such that calculating the available electric energy from the PSU comprises calculating the available electric energy from the PSU using a value representative of electric energy usage at the CPE operating with maximum upstream and downstream data throughputs with a foreign exchange subscriber port ringing even; and
the stored processing system-executable instructions are configured to cause the processing system to perform operations further comprising determining whether the available electric energy from the PSU exceeds a charge threshold.

35. The non-transitory processor-readable medium of claim 28, wherein the stored processing system-executable instructions are configured to cause the processing system to perform operation further comprising streaming battery status information from the CPE to a remote monitoring device.

36. The non-transitory processor-readable medium of claim 28, wherein the stored processing system-executable instructions are configured to cause the processing system to perform operation further comprising receiving, at the CPE, a battery charge command from a remote monitoring device, wherein charging the at least one battery of the CPE using the available electric energy from the PSU comprises charging the at least one battery of the CPE in response to receiving the battery charge command.
